(19) United States
(12) Patent Application Publication
(10) Pub. No.: US 2011/0226511 A1
(43) Pub. Date: Sep. 22, 2011

(54) INKJET INK, SURFACE METAL FILM MATERIAL AND ITS MANUFACTURING METHOD, AND PATTERNED METAL MATERIAL AND ITS MANUFACTURING METHOD

(75) Inventor: Yasuaki MATSUSHITA, Ashigara-kami-gun (JP)

(73) Assignee: FUJIFILM CORPORATION, Tokyo (JP)

(21) Appl. No.: 13/051,203

(22) Filed: Mar. 18, 2011

(30) Foreign Application Priority Data
Mar. 19, 2010 (JP) 2010-064901

(51) Int. Cl. H05K 1/09; B41J 2/015; C08L 33/18; C08L 39/00; B32B 3/10; B05D 1/38; B05D 3/02; B05D 3/06; C23F 1/00

(52) U.S. Cl. 174/250; 347/20; 524/555; 428/201; 427/512; 427/385.5; 216/100

(57) ABSTRACT

An inkjet ink includes a polymer which contains a functional group capable of forming an interaction with a plating catalyst or its precursor and a polymerizable functional group; and at least one solvent in which the polymer is dissolved or dispersed. The inkjet ink is capable of forming in a desired pattern a polymer layer having excellent adhesion to a metal film (plated film) and exhibits high stability in continuous discharge.

### BACKGROUND OF THE INVENTION

The present invention relates to an inkjet ink, a surface metal film material and its manufacturing method, and a patterned metal material and its manufacturing method. More specifically, the invention relates to an inkjet ink which contains a polymer having a specified functional group and a solvent having a specified boiling point, a surface metal film material obtained using the inkjet ink, a patterned metal material, and their manufacturing methods.

Metal circuit boards having patterned metal interconnects formed on a surface of an insulating substrate have heretofore been widely used in electronic components and semiconductor devices.

A “subtractive” process is mainly used to produce the patterned metal material. The subtractive process is a process which involves forming a photosensitive layer capable of being sensitized by irradiation with actinic rays on a metal film formed on a surface of a substrate, imagewise exposing the photosensitive layer, developing the exposed photosensitive layer to form a resist image, etching the metal film to form a metal pattern and finally peeling off the resist.

In the metal pattern obtained by this method, the adhesion between the substrate and the metal film is achieved by the anchor effect produced by forming irregularities at the surface of the substrate. Therefore, when used as metal wiring, the metal pattern suffered from poor radio frequency characteristics due to the irregularities of the resulting metal pattern at the interface with the substrate. Further, the surface of the substrate needs to be treated with a strong acid such as chromic acid for roughening and therefore, a complicated process is necessary to obtain a metal pattern having excellent adhesion between the metal film and the substrate.

As a means to solve this problem, a method described in JP 2009-503806 A is known which involves producing on a substrate a graft polymer directly bonded to the substrate to form a patterned polymer layer and plating the polymer layer to form a metal film thereon to thereby obtain a metal pattern (conductive pattern). This method enables the adhesion between the substrate and the metal film to be improved without roughening the surface of the substrate.

### SUMMARY OF THE INVENTION

According to JP 2009-503806 A, a liquid containing a radical polymerizable unsaturated compound is disposed in a pattern shape by an inkjet system to obtain the graft polymer directly bonded to the surface of the substrate.

On the other hand, in response to an increasing demand for the reduction of semiconductor device costs and the improvement of production efficiency, it has been desired to manufacture substrates having a predetermined metal pattern with higher productivity. In cases where the graft polymer layer for enhancing the adhesion between the substrate and the metal film is continuously manufactured by the inkjet system as described in JP 2009-503806 A, nozzle clogging during the ink discharge may adversely affect the whole of the production process and therefore high stability is required in continuous discharge.

With the trend toward smaller sizes and higher densities of semiconductor devices, it has been required to manufacture wiring with narrower line width and having no disconnection. Therefore, it has been desired to manufacture a patterned polymer layer with a uniform line width and having no disconnection also in the manufacture of the foregoing graft polymer layer.

According to the study the inventors of the invention made on the stability in continuous discharge with the use of the liquid containing the radical polymerizable unsaturated compound specifically described in JP 2009-503806 A, this technique did not satisfy the level required in recent years for the stability in continuous discharge and required further improvement.

The inventors of the invention also made a study on the patternability of the graft polymer layer with the use of the liquid and as a result defects such as increase in the line width and pattern disconnection sometimes occurred.

In addition, higher insulation properties are recently required between the metal pattern interconnects in a printed circuit board or other micro wiring and further improvement is necessary in the interconnect insulation reliability.

Under these circumstances, a first object of the invention is to provide an inkjet ink which is capable of forming in a desired pattern a polymer layer having excellent adhesion to a metal film (plated film) and exhibits high stability in continuous discharge.

A second object of the invention is to provide a surface metal film material which has excellent adhesion between a metal film and a substrate and is obtained using the inkjet ink, and its manufacturing method.

A third object of the invention is to provide a patterned metal material having excellent insulation reliability in areas where no metal pattern is formed, and its manufacturing method.

The inventors of the invention have made an intensive study on these objects and as a result found that the objects can be achieved by using an inkjet ink which contains a polymer having a specified functional group and at least one solvent having a specified boiling point.

Accordingly, the inventors of the invention have found that the objects can be achieved by the characteristic features as described below.

(1) An inkjet ink comprising:

a polymer which contains a functional group capable of forming an interaction with a plating catalyst or its precursor and a polymerizable functional group; and

at least one solvent in which the polymer is dissolved or dispersed,

wherein an average boiling point (T_{(b)}) of the at least one solvent represented by formula (A) as described below is at least 150° C.

(2) The inkjet ink according to (1), wherein the at least one solvent is a solvent mixture containing a solvent A with a boiling point of less than 180° C. and a solvent B with a boiling point of 180° C. or more and the solvent A is contained more than the solvent B on a weight basis.
(3) The inkjet ink according to (1) or (2), wherein the inkjet ink has a viscosity at 25° C. of 50 mPa·s or less.
(4) The inkjet ink according to any one of (1) to (3), wherein the inkjet ink has a surface tension at 25° C. of 20 to 40 mN/m.
(5) The inkjet ink according to any one of (1) to (4), wherein the functional group capable of forming the interaction with the plating catalyst or its precursor is a non-dissociative functional group.
(6) The inkjet ink according to any one of (1) to (5), wherein the polymer has units represented by formulas (1) and (2) as described below.
(7) The inkjet ink according to any one of (1) to (6), wherein the polymer is contained in an amount of 1 to 20 wt % and the at least one solvent is contained in an amount of 80 to 99 wt %.
(8) The inkjet ink according to any one of (1) to (7), wherein the inkjet ink is used to form a polymer layer which is receptive to the plating catalyst or its precursor.
(9) A method of manufacturing a surface metal film material having a metal film on a surface of a polymer layer, the method comprising:

a layer-forming step which includes applying the inkjet ink according to any one of (1) to (8) onto a substrate by an inkjet system and curing the applied ink by heating or by exposure to light to form the polymer layer;

a catalyst applying step which includes applying a plating catalyst or its precursor to the polymer layer; and

a plating step which includes plating polymer layer with the plating catalyst or its precursor.

(10) The method according to (9), wherein the plating step is an electroless plating step and the metal film obtained by the electroless plating step has a thickness of 0.2 to 2.0 μm.
(11) A surface metal film material obtained by the method according to (9) or (10).
(12) A method of manufacturing a patterned metal material comprising: a step of pattern-etching a metal film in the surface metal film material according to (11).
(13) A circuit board comprising a patterned metal material obtained by the method according to (12).
(14) A decorative material using the surface metal film material according to (11).
(15) A method of manufacturing a patterned metal material having a patterned metal film on a surface of a polymer film, the method comprising:

a layer-forming step which includes applying the inkjet ink according to any one of (1) to (8) onto a substrate in a pattern shape by an inkjet system and curing the applied ink by heating or by exposure to light to form the polymer layer in the pattern shape;

a catalyst applying step which includes applying a plating catalyst or its precursor to the polymer layer; and

a plating step which includes plating the polymer layer with the plating catalyst or its precursor.

The invention can provide an inkjet ink which is capable of forming in a desired pattern a polymer layer having excellent adhesion to a metal film (plated film) and exhibits high stability in continuous discharge.

The invention can provide a surface metal film material which has excellent adhesion between a metal film and a substrate and is obtained using the inkjet ink, and its manufacturing method.

The invention can provide a patterned metal material having excellent insulation reliability in areas where no metal pattern is formed, and its manufacturing method.

### DETAILED DESCRIPTION OF THE INVENTION

The inkjet ink (ink for use in an inkjet system), the surface metal film material and its manufacturing method, and the patterned metal material and its manufacturing method according to the invention are described below in detail.

The inkjet ink of the invention contains a polymer having a specified functional group and at least one solvent having a specified boiling point. The solvent having the specified boiling point enables the ink obtained to exhibit excellent continuous discharge stability and patternability. The effect is particularly noticeable when using a solvent mixture containing a solvent having a boiling point of less than 180° C. and a solvent having a boiling point of 180° C. or more, because the solvent having a high boiling point contributes to suppressing nozzle clogging, and when the ink contacts the substrate, most of the solvent having a low boiling point volatilizes to increase the ink viscosity, as a result of which ink spreading is suppressed to achieve excellent patterning performance.

The polymer and the solvent(s) contained in the inkjet ink are first described in detail.

[Polymer]

The polymer used in the inkjet ink of the invention is a polymer which contains a functional group capable of forming an interaction with a plating catalyst or its precursor (hereinafter sometimes referred to as “interactive group”) and a polymerizable functional group. The interactive group included in the polymer contributes to achieving excellent adsorption on the plating catalyst to be described later, as a result of which a plated film (metal film) with a sufficient thickness can be obtained in the plating treatment. The polymerizable functional group included in the polymer contributes to exhibiting high adhesion to a substrate to be described later and causes a cross-linking reaction to proceed in the film, whereby a polymer layer with a high strength can be obtained.

(Interactive Group)

The type of the interactive group is not particularly limited as long as it forms an interaction with a plating catalyst to be described later. Examples of the interactive group include a polar group (hydrophilic group) and a group capable of multidentate coordination, a nitrogen-containing functional group, a sulfur-containing functional group, an oxygen-containing functional group and other non-dissociative functional groups (functional groups in which no proton is generated by dissociation). It is particularly preferred to use a non-dissociative functional group in the moiety showing metal ion adsorptivity in order to reduce water absorbability and hygroscopicity of the polymer layer obtained using the ink.

Examples of the polar group include positively charged functional groups such as ammonium and phosphonium, negatively charged groups such as sulfonate group, carboxyl group, phosphate group, phosphonate group, N-hydroxy structure-containing group, phenolic hydroxyl group and hydroxyl group, and acid groups which may be dissociated into a negatively charged state. Each of them is attached by adsorption to a metal ion either in the form of a counterion derived from the dissociative group or in a non-dissociated form.

More specifically, the non-dissociative functional group is preferably selected from among a group capable of coordination with a metal ion, a nitrogen-containing functional group, a sulfur-containing functional group, an oxygen-containing functional group and a phosphorous-containing functional group. More specific examples thereof include nitrogen-containing functional groups such as imide group, pyridine group, tertiary amino group, ammonium group, pyrrolidone group, amidino group, triazine ring, triazole ring, benzotriazole group, benzimidazole group, quinoline group, pyrimidine group, pyrazine group, nazoline group, quinoxaline group, purine group, triazine group, piperidine group, piperazine group, pyrrolidine group, pyrazole group, aniline group, alkylamine group structure-containing group, isocyanuric structure-containing group, nitro group, nitroso group, azo group, diazo group, azide group, cyano group, and cyanate group (R—O—CN); oxygen-containing functional groups such as ether group, carbonyl group, ester group, N-oxide structure-containing group and S-oxide structure-containing group; sulfur-containing functional groups such as thioether group, thioxy group, thiophene group, thiol group, sulfoxide group, sulfone group, sulfide group, sulfoxyimine structure-containing group, sulfoxinium salt structure-containing group and sulfonic ester structure-containing group; phosphorous-containing functional groups such as phosphine group, phosphate group, and phosphoramide group; groups containing halogen atoms such as chlorine and bromine. In an embodiment showing no dissociation because of the relation with the neighboring atom or atom group, imidazole group, urea group or thiourea group may be used. In addition, the non-dissociative functional group may be one derived from a compound having inclusion ability such as cyclodextrin and crown ether.

Of these, ether group (more specifically a structure represented by —O—(CH₂)ₙ—O— (n is an integer of 1 to 5)) or cyano group is particularly preferred and cyano group is more preferred in terms of high polarity and high adsorptivity on a plating catalyst.

(Polymerizable Group)

Examples of the polymerizable group include a radical polymerizable group and a cationic polymerizable group, and a radical polymerizable group is preferred in terms of the reactivity with the substrate to be described later. Examples of the radical polymerizable group include unsaturated carboxylic ester groups such as acrylic ester group, methacrylic ester group, itaconic ester group, crotonic ester group, isocrotonic ester group and maleic ester group; styryl group and allyl group. Of these, methacrylic ester group (methacryloyloxy group), acrylic ester group (acryloyloxy group), allyl group and styryl group are preferred and acryloyloxy group and methacryloyloxy group are particularly preferred.

[Preferred Embodiment of Polymer]

### (Unit Represented by Formula (1))

A preferred embodiment of the polymer is a polymer having a unit (recurring unit) represented by formula (1) in terms of higher reactivity with the substrate. The unit is one having a polymerizable group. This unit is hereinafter referred to as “polymerizable group-containing unit.”

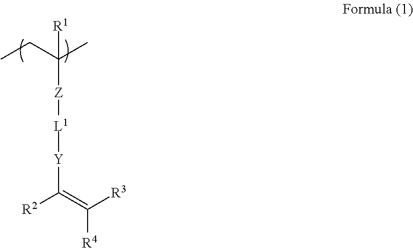

In formula (1), R¹ to R⁴ are each independently a hydrogen atom or an optionally substituted alkyl group.

When R¹ to R⁴ are each an optionally substituted alkyl group, an alkyl group containing 1 to 4 carbon atoms is preferred and an alkyl group containing 1 or 2 carbon atoms is more preferred. More specific examples of the unsubstituted alkyl group include methyl group, ethyl group, propyl group and butyl group. Examples of the substituted alkyl group include methyl group, ethyl group, propyl group and butyl group substituted with methoxy group, hydroxy group or halogen atoms such as chlorine atom, bromine atom and fluorine atom.

R¹ is preferably a hydrogen atom or a methyl group optionally substituted with a hydroxy group or a bromine atom.

R² is preferably a hydrogen atom or a methyl group optionally substituted with a hydroxy group or a bromine atom.

R³ is preferably a hydrogen atom.

R⁴ is preferably a hydrogen atom.

Y and Z are each independently a single bond or an optionally substituted divalent organic group. Examples of the divalent organic group include optionally substituted aliphatic hydrocarbon groups preferably containing 1 to 11 carbon atoms, optionally substituted aromatic hydrocarbon groups preferably containing 6 to 12 carbon atoms, —O—, —S—, —N(R)— (R: alkyl group), —CO—, —NH—, —COO—, —CONH—, or combination groups thereof such as alkyleneoxy group, alkyleneoxycarbonyl group and alkylenecarbonyloxy group. These organic groups may have a substituent such as hydroxy group as long as the effects of the invention are not impaired.

Preferred examples of the optionally substituted aliphatic hydrocarbon group (e.g., alkylene group) include methylene group, ethylene group, propylene group, butylene group, pentylene group, and hexylene group which are optionally substituted with methoxy group, hydroxy group or halogen atoms such as chlorine atom, bromine atom and fluorine atom.

Preferred examples of the optionally substituted aromatic hydrocarbon group include unsubstituted arylene group (e.g., phenylene group) and phenylene group substituted with methoxy group, hydroxy group or halogen atoms such as chlorine atom, bromine atom and fluorine atom.

Y and Z are each preferably an ester group (—COO—), an amide group (—CONH—), an ether group (—O—), or an optionally substituted aromatic hydrocarbon group.

L¹ is an optionally substituted divalent organic group. The divalent organic group is as defined for the organic groups represented by Y and Z and examples thereof include optionally substituted aliphatic hydrocarbon groups, optionally substituted aromatic hydrocarbon groups, —O—, —S—, —N(R)— (R: alkyl group), —CO—, —NH—, —COO—, —CONH—, or combination groups thereof.

L¹ is preferably an unsubstituted alkylene group or a divalent organic group having a urethane bond or a urea bond, is more preferably an unsubstituted alkylene group or a divalent organic group having a urethane bond, and most preferably contains in total 1 to 9 carbon atoms. The total number of carbon atoms in L¹ refers to the total number of carbon atoms included in the optionally substituted divalent organic group represented by L¹.

More specifically, L¹ preferably has a structure represented by formula (1-1), (1-2) or (1-3).

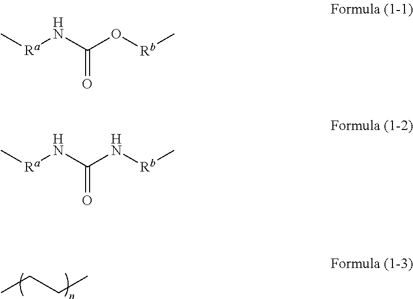

In formulas (1-1) and (1-2), R^{a} and R^{b} are each independently a divalent organic group formed with at least two atoms selected from the group consisting of carbon atom, hydrogen atom and oxygen atom. Preferred examples thereof include optionally substituted methylene, ethylene, propylene and butylene groups, ethylene oxide group, diethylene oxide group, triethylene oxide group, tetraethylene oxide group, dipropylene oxide group, tripropylene oxide group, and tetrapropylene oxide group. In formula (I-3), n is an integer from 1 to 10.

(Unit Represented by Formula (4))

A preferred embodiment of the unit represented by formula (1) is a unit represented by formula (4):

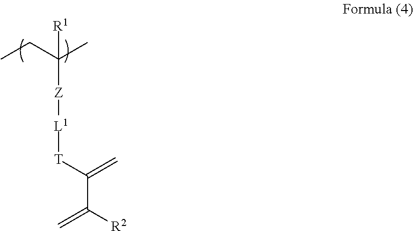

wherein R¹, R², Z and L¹ are as defined for the groups in the unit represented by formula (1) and T is an oxygen atom or NR (R is a hydrogen atom or an alkyl group and preferably a hydrogen atom or an unsubstituted alkyl group containing 1 to 5 carbon atoms).

(Unit Represented by Formula (5))

A preferred embodiment of the unit represented by formula (4) is a unit represented by formula (5):

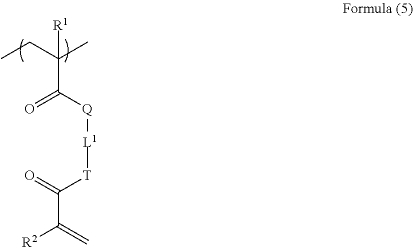

wherein R¹, R² and L¹ are as defined for the groups in the unit represented by formula (1), and T and Q are each independently an oxygen atom or NR (R is a hydrogen atom or an alkyl group and is preferably a hydrogen atom or an unsubstituted alkyl group containing 1 to 5 carbon atoms).

In formulas (4) and (5), T is preferably an oxygen atom.

In formulas (4) and (5), L¹ is preferably an unsubstituted alkylene group or a divalent organic group having a urethane bond or a urea bond, is more preferably a divalent organic group having a urethane bond, and most preferably contains in total 1 to 9 carbons.

The content of the unit represented by formula (1) in the polymer is not particularly limited and is preferably from 5 to 50 mol %, more preferably from 5 to 40 mol % and most preferably from 10 to 40 mol % with respect to all the units (100 mol %) in terms of the adhesion to the substrate to be described later, storage stability and degree of difficulty of the synthesis. At a content of less than 5 mol %, the reactivity (curing properties, polymerizability) may be reduced, whereas at a content in excess of 50 mol %, gelation easily occurs during the synthesis of the polymer, making it difficult to control the reaction.

(Unit Represented by Formula (2))

A preferred embodiment of the polymer is a polymer having a unit (recurring unit) represented by formula (2) in terms of the excellent adsorptivity on the plating catalyst. This unit is one containing an interactive group (interactive group-containing unit).

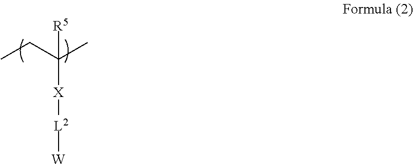

In formula (2), R⁵ is a hydrogen atom or an optionally substituted alkyl group. The optionally substituted alkyl group represented by R⁵ is as defined for the optionally substituted alkyl groups represented by R¹ to R⁴.

R⁵ is preferably a hydrogen atom, or a methyl group optionally substituted with a hydroxy group or a bromine atom.

X and L² are each independently a single bond or an optionally substituted divalent organic group. The divalent organic group is as defined above.

X is preferably a single bond, an ester group, an amide group or an ether group, more preferably a single bond, an ester group or an amide group, and most preferably a single bond or an ester group.

In a preferred embodiment, L² is a linear, branched or cyclic alkylene group, an aromatic group (preferably an aromatic hydrocarbon group), or a combination group thereof. The combination group of the alkylene group and the aromatic group may further contain an ether group, an ester group, an amide group, a urethane group or a urea group. In particular, the total number of carbon atoms included in L² is preferably 1 to 15 and it is particularly preferred for L² to be unsubstituted. The total number of carbon atoms refers to the total number of carbon atoms included in the optionally substituted divalent organic group represented by L².

Specific examples thereof include methylene group, ethylene group, propylene group, butylene group and phenylene group which may be optionally substituted with methoxy group, hydroxyl group, chlorine atom, bromine atom or fluorine atom, and combination groups thereof.

W is a functional group capable of forming an interaction with the plating catalyst or its precursor. W may be directly bonded to the polymer linear chain. In other words, a combination in which X and L² are each a single bond and W is directly bonded to a carbon atom is also possible. The functional group is as defined above.

A preferred embodiment of the unit represented by formula (2) is a unit represented by formula (6):

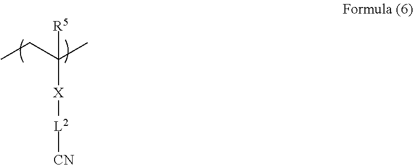

wherein R⁵, X and L² are as defined for the groups in formula (2).

Another preferred embodiment of the unit represented by formula (2) is a unit represented by formula (7):

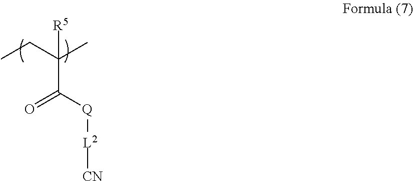

wherein R⁵ and L² are as defined for the groups in formula (2).

Q is an oxygen atom or NR′ (where R′ is a hydrogen atom or an alkyl group and preferably a hydrogen atom or an unsubstituted alkyl group having 1 to 5 carbon atoms).

The content of the unit represented by formula (2) in the polymer is not particularly limited and is preferably from 20 to 90 mol % and more preferably from 30 to 80 mol % with respect to all the units (100 mol %) in the polymer in terms of the adsorptivity on the plating catalyst or its precursor and ease of synthesis.

(Optional Unit)

The polymer may further contain a unit represented by formula (3) in terms of improved affinity for the aqueous solution and further improved developability. The unit corresponds to a unit having an ionic polar group.

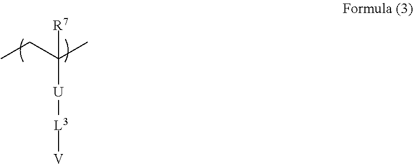

In formula (3), R⁷ is a hydrogen atom or an optionally substituted alkyl group. The optionally substituted alkyl group represented by R⁷ is as defined for the optionally substituted alkyl groups represented by R¹ to R⁴.

R⁷ is preferably a hydrogen atom or a methyl group optionally substituted with a hydroxy group or a bromine atom.

U and L³ are each independently a single bond or an optionally substituted divalent organic group. The divalent organic group is as defined above.

A preferred embodiment of U is the same as the preferred embodiment of X.

A preferred embodiment of L³ is the same as the preferred embodiment of L².

V is not particularly limited as long as it represents an ionic polar group and imparts developability to the aqueous polymer solution. Specific examples thereof include carboxylic acid group, sulfonic acid group, phosphoric acid group, and boronic acid group. In particular, carboxylic acid group is preferred in terms of the proper acidity (causing no decomposition of other functional group), and carboxylic acid group directly bonded to the polymer main chain, carboxylic acid group directly bonded to the alicyclic structure (alicyclic carboxylic acid group) and carboxylic acid group separated from the polymer main chain (long-chain carboxylic acid group) are preferred and carboxylic acid group directly bonded to the polymer main chain is most preferred in terms of compatibility with low water absorbability necessary for electric wiring.

Such an ionic polar group may be introduced into the polymer by addition to part of the polymer for substitution or by copolymerizing a monomer with a pendant ionic polar group.

In the unit represented by formula (3), an embodiment in which V is a carboxylic acid group and a 4- to 8-membered ring structure is present in the linkage portion of L³ with V is preferred in terms of proper acidity (causing no decomposition of other functional group), hydrophilicity in an aqueous alkali solution, and hydrophobicity easily shown upon dehydration due to the cyclic structure. Examples of the 4- to 8-membered ring structure include cyclobutyl group, cyclopentyl group, cyclohexyl group, cycloheptyl group, cyclooctyl group, and phenylene group. Of these, cyclohexyl group and phenylene group are preferred. In other words, in this embodiment, the unit represented by formula (3) has an alicyclic carboxylic acid group at the end.

In the unit represented by formula (3), an embodiment in which V is a carboxylic acid group and L³ has a chain length of 6 to 18 atoms is preferred in terms of proper acidity (causing no decomposition of other functional group), hydrophilicity in an aqueous alkali solution, and hydrophobicity easily shown upon dehydration due to the long-chain alkyl group structure. The chain length of L³ refers to a distance between U and V in formula (3) and U is preferably spaced apart from V by a distance of 6 to 18 atoms. L³ has a chain length of more preferably 6 to 14 atoms and even more preferably 6 to 12 atoms.

On the other hand, in a preferred embodiment of the unit represented by formula (3), V is a carboxylic acid group and U and L³ are each a single bond. In this embodiment, the carboxylic acid group is considered to be surrounded by the polymer main chain. As a result, the polymer can be rendered hydrophobic to enhance the adhesion between the substrate and a metal pattern just after the formation thereof and also the water resistance of the polymer layer.

The content of the unit represented by formula (3) in the polymer is not particularly limited and is preferably from 5 to 70 mol % and more preferably from 20 to 60 mol % with respect to all the units (100 mol %) in the polymer in terms of the developability using the aqueous solution and resistance to wet adhesion. The unit content is most preferably from 30 to 50 mol %. At a unit content within the foregoing range, a better balance can be achieved between the developability and the resistance to wet adhesion.

The linking mode of the units in the polymer is not particularly limited and the polymer may be a random polymer formed by random linking of the units or a block polymer in which each unit of the same type is repeatedly linked to form a block.

The polymer of the invention may contain other units than the above as long as the effects of the invention are not impaired.

However, in cases where a polymerizable group is introduced into the polymer through a reaction as will be described later, if the polymerizable group is difficult to completely introduce, a small amount of reactive moiety may remain to serve as other unit.

Preferred embodiments of the polymer of the invention include a polymer having the units represented by formulas (1) and (6), a polymer having the units represented by formulas (1) and (7), and a polymer having the units represented by formulas (1), (2) and (3). A polymer having the units represented by formulas (1) and (2) and having substantially no unit represented by formula (3) is particularly preferred in terms of the adhesion of the plated layer in the patterned metal material obtained using the polymer and the insulation reliability.

The weight-average molecular weight of the polymer of the invention is not particularly limited and is preferably from 1,000 to 200,000 and more preferably from 2,000 to 100,000. The polymer of the invention preferably has a weight-average molecular weight of 8,000 to 50,000 in terms of the stability in inkjet discharge, polymerization sensitivity and adhesion.

The degree of polymerization of the polymer in the invention is preferably 10 or more and more preferably 20 or more but is preferably up to 2,000 and most preferably up to 1,000.

[Polymer Synthesis Method]

The polymer synthesis method is not particularly limited and the monomer used may be a commercial product or a product synthesized by a combination of known synthesis methods. The following methods are preferably used to synthesize the polymer.

Exemplary methods include i) a method in which a monomer having an interactive group and a monomer having a polymerizable group are copolymerized, ii) a method in which a monomer having an interactive group and a monomer having a double bond precursor are copolymerized and a double bond is then introduced by a treatment with a base, and iii) a method in which a monomer having an interactive group and a monomer having a reactive group for double bond introduction are copolymerized and the resulting polymer having the reactive group is reacted with a monomer having a polymerizable group which may react with the reactive group, thereby introducing the double bond or the polymerizable group.

The methods ii) and iii) are preferred in terms of the synthesis suitability. The type of polymerization reaction in the synthesis is not particularly limited. Examples thereof include radical polymerization, cationic polymerization and anionic polymerization, and radical polymerization is preferred. In the case of introducing the unit having an ionic polar group, a monomer having an ionic polar group is used in combination.

The polymer of the invention may be synthesized according to the method described in paragraphs [0097] to [0125] of JP 2009-280905 A.

More specifically, in order to convert the double bond precursor to the double bond in The synthesis method ii), a process in which leaving groups represented by B and C are removed by an elimination reaction as described below, in other words, a reaction in which C is pulled out by the action of a base to eliminate B is used.

In the following formula, A is an organic group having a polymerizable group, R¹ to R³ are each independently a hydrogen atom or a monovalent organic group, B and C are each independently a leaving group removed by the elimination reaction, one of B and C is a hydrogen atom and the other is a halogen atom, a sulfonic ester group, an ether group or a thioether group. The elimination reaction as used herein pulls out C under the action of a base to eliminate B. B and C are preferably eliminated as an anion and a cation, respectively.

Preferred examples of the base include hydrides, hydroxides and carbonates of alkali metals, organic amine compounds and metal alkoxide compounds.

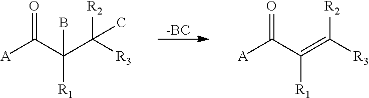

A monomer having a reactive group such as carboxyl group, hydroxyl group, epoxy group or isocyanate group is used in the synthesis method iii) as the monomer having a reactive group for double bond introduction.

The polymerizable group-containing monomer to be reacted with the reactive group-containing polymer preferably has a reactive group such as carboxyl group, hydroxyl group, epoxy group, isocyanate group or a halogenated benzyl group.

Exemplary patterns of the combination between the reactive group in the polymer and the reactive group in the monomer include a combination of carboxyl group and epoxy group, a combination of carboxyl group and isocyanate group, a combination of hydroxyl group and epoxy group, a combination of hydroxyl group and isocynate group, a combination of isocyanate group and hydroxyl group, a combination of isocyanate group and carboxyl group, and a combination of epoxy group and carboxyl group (the former group refers to the reactive group in the polymer and the latter group to the reactive group in the monomer).

In the polymer synthesis method of the invention, it is preferred to form a urethane bond in L¹ by using a polymer having hydroxyl group on the side chain and a compound having isocyanate group and a polymerizable group and adding the isocyanate group to the hydroxyl group.

In the polymer synthesis method of the invention, it is also preferred to form a methylene group in L¹ by using a polymer having carboxyl group on the side chain and a compound having a halogenated benzyl group and a polymerizable group and adding the halogenated benzyl group to the carboxyl group.

[Solvent]

The inkjet ink of the invention contains solvents (liquids) which satisfy the average boiling point represented by formula (A). The above-described polymer can be dissolved or dispersed in the solvents. In the practice of the invention, an ink having excellent stability in continuous discharge and excellent formability of the polymer layer can be obtained by using solvents with predetermined boiling points.

The solvents (liquids) used in the inkjet ink have an average boiling point represented by formula (A) of 150° C. or more.

$${T}_{( b )} = {\sum }_{i = 1}^{n} ( {W}_{i} \times {T}_{bi} ) \qquad Formula ( A )$$

In formula (A), Wᵢ represents the weight ratio of the weight of the ith solvent in the inkjet ink to the total weight of the solvents (weight of the ith solvent/total weight of the solvents) (weight fraction %).

T_{bi} represents the boiling point (° C.) of the ith solvent in the inkjet ink at 1 atm. i represents an integer of 1 to n.

n represents the number of solvents included in the inkjet ink and more specifically an integer of 1 or more. For example, n is 2 when two solvents are used and 3 when three solvents are used. The upper limit of n is not particularly limited and is preferably up to 5 and more preferably up to 3 in terms of the cost.

In formula (A), Σ represents the sum.

In formula (A), the boiling point value of each solvent is multiplied by the weight fraction of the solvent to all the solvents and the sum of the resulting values is determined. The resulting value is useful to estimate the degree of volatilization of the solvents in the inkjet ink.

More specifically, in the case of using only one solvent, n is 1 and the boiling point value of the solvent used corresponds to T_{(b)}.

In the case of using two solvents in combination, T_{(b)} can be determined by the following formula:

T_{(b)}={T_{X}×(weight of solvent X/total solvent weight)}+{T_{Y}×(weight of solvent Y/total solvent weight)}

where T_{X} represents the boiling point of solvent X and T_{Y} represents the boiling point of solvent Y.

In addition, in the case of using three solvents in combination, T_{(b)} can be determined by the following formula:

T_{(b)}={T_{X}×(weight of solvent X/total solvent weight)}+{T_{Y}×(weight of solvent Y/total solvent weight)}+{T_{Z}×(weight of solvent Z/total solvent weight)}

where Tₓ represents the boiling point of solvent X, T_{Y} represents the boiling point of solvent Y and T_{Z} represents the boiling point of solvent Z.

In the practice of the invention, T_{(b)} represented by formula (A) is at least 150° C. but is preferably at least 155° C. and more preferably at least 160° C. because the stability in continuous ink discharge and the formability of the polymer layer are more excellent. The upper limit is not particularly limited but in general T_{(b)} is preferably up to 270° C. and more preferably up to 240° C.

The solvent used may be a non-polymerizable solvent (non-polymerizable liquid) or a polymerizable solvent (polymerizable liquid) containing a polymerizable group. The polymerizable solvent refers to a liquid monomer having a polymerizable group. The polymerizable solvent is not particularly limited as long as it has a sufficient viscosity to enable the ink to be discharged. In terms of the solubility, it is particularly preferred to use a solvent with a molecular weight of 300 or less which includes up to 2 polymerizable functional groups.

More specifically, examples of the solvent used include aldehyde solvents (e.g., solvents with a boiling point of less than 180° C. such as 2-aldehyde and benzaldehyde); ether solvents (e.g., solvents with a boiling point of less than 180° C. such as ethylene glycol dimethyl ether, 1,4-dioxane, propylene glycol monomethyl ether, ethylene glycol monomethyl ethyl acetate, and dipropylene glycol dimethyl ether, solvents with a boiling point of 180° C. or more such as dipropylene glycol monomethyl ether acetate, diethylene glycol diethyl ether, dipropylene glycol monomethyl ether, ethylene glycol monohexyl ether, triethylene glycol monomethyl ether, and tetraethylene glycol dimethyl ether); amide solvents (solvents with a boiling point of less than 180° C. such as N,N-dimethylformamide and N,N-dimethylacetamide, and solvents with a boiling point of 180° C. or more such as N-methylformamide, N-methylacetamide and 1-methyl-2-pyrrolidone); amine solvents (e.g., solvents with a boiling point of less than 180° C. such as triethylamine and pyridine); aliphatic hydrocarbon solvents (e.g., solvents with a boiling point of less than 180° C. such as cyclohexane and heptane); aromatic hydrocarbon solvents (e.g., solvents with a boiling point of less than 180° C. such as benzene, toluene and xylene, solvents with a boiling point of 180° C. or more such as aniline, cresol and tetralin); alcohol solvents (e.g., solvents with a boiling point of less than 180° C. such as ethanol, butanol, hexanol and methylcyclohexanol and solvents with a boiling point of 180° C. or more such as glycerol, 2-ethyl-1-hexanol, benzyl alcohol and decanol); ester solvents (e.g., solvents with a boiling point of less than 180° C. such as ethyl acetate, propyl acetate, diethyl carbonate and ethyl lactate, and solvents with a boiling point of 180° C. or more such as 2-ethoxyethyl acetate, ethyl benzoate, propylene carbonate and triacetin); ketone solvents (e.g., solvents with a boiling point of less than 180° C. such as 2-butanone and cyclohexanone, and solvents with a boiling point of 180° C. or more such as acetophenone); nitrile solvents (e.g., solvents with a boiling point of less than 180° C. such as acetonitrile, and solvents with a boiling point of 180° C. or more such as cyanoethyl acrylate); halogen solvents (e.g., trichloromethane and tetrachloromethane); sulfur solvents (e.g., dimethyl sulfoxide), and organic acids (e.g., acetic acid).

Of these, alcohol solvents, ester solvents and ether solvents (in particular (oligo)ethylene glycol derivatives, (oligo)propylene glycol derivatives) and polymerizable solvents are preferred in terms of the solubility, aggressiveness of the inkjet head and selectivity of materials.

In the invention, the solvents may be used alone or in combination of two or more.

### PREFERRED EMBODIMENTS

A preferred embodiment of the solvent used is a solvent mixture containing at least a solvent A with a boiling point of less than 180° C. and a solvent B with a boiling point of 180° C. or more. The solvent used is more preferably a solvent mixture containing the solvent A more than solvent B on the weight basis. The use of the solvent mixture improves the surface state of the polymer film during the drawing while retaining excellent stability in continuous discharge, leading to an improvement of the accuracy in the drawing of narrow lines.

In this preferred embodiment, the solvents A and B are each composed of two or more types of solvent.

The solvent A refers to a solvent with a boiling point of less than 180° C. at 1 atm. The solvent A has a boiling point of more preferably up to 150° C. and most preferably up to 140° C. because the solvent vaporizes immediately after the discharge from the inkjet head to thicken the ink component. As for the lower limit, the boiling point is preferably at least 70° C. and more preferably at least 90° C.

The solvent B refers to a solvent with a boiling point of 180° C. or more at 1 atm. The solvent B has a boiling point of more preferably at least 200° C. and most preferably at least 220° C. in terms of suppressing the drying of the inkjet head and imparting excellent stability in continuous discharge. The upper limit of the boiling point is not particularly limited and is preferably up to 330° C. and more preferably up to 300° C.

The difference in the boiling point between the solvents A and B is not particularly limited but is preferably at least 50° C. and more preferably at least 70° C. because the effects of the invention are more excellent. There is no particular upper limit but usually the difference is preferably up to 250° C. and more preferably up to 200° C.

In cases where the solvent A (or solvent B) used is composed of at least two types of solvent, the boiling point value of each solvent A is multiplied by the weight fraction of the solvent A to the total amount of the solvents A and the sum of the resulting values is regarded as the boiling point of the solvents A. The same holds true for the solvent B. More specifically, each solvent has a boiling point represented by formula (B) or (C).

$$\begin{matrix}{T}_{A ( b )} = {\sum }_{i = 1}^{{n}_{A}} ( {W}_{Ai} \times {T}_{Abi} ) & Formula ( B ) \\ {T}_{B ( b )} = {\sum }_{i = 1}^{{n}_{B}} ( {W}_{Bi} \times {T}_{Bbi} ) & Formula ( C )\end{matrix}$$

In formula (B), W_{Ai} represents the weight ratio of the ith solvent A in the inkjet ink to the total weight of the solvents A (weight of the ith solvent A/total weight of the solvents A) (weight fraction).

T_{Abi} represents the boiling point (° C.) of the ith solvent A in the inkjet ink at 1 atm. i represents an integer of 1 to n_{A}.

n_{A} represents the number of solvents A included in the inkjet ink and more specifically an integer of 1 or more. For example, n_{A} is 2 when two solvents A are used and is 3 when three solvents A are used. There is no particular upper limit but n_{A} is preferably up to 5 and more preferably up to 3 in terms of the cost.

In formula (B), Σ represents the sum.

In formula (C), W_{Bi} represents the weight ratio of the ith solvent B in the inkjet ink to the total weight of the solvents B (weight of the ith solvent B/total weight of the solvents B) (weight fraction).

T_{Bbi} represents the boiling point (° C.) of the ith solvent B in the inkjet ink at 1 atm. i represents an integer of 1 to n_{B}.

n_{B} represents the number of solvents B included in the inkjet ink and more specifically an integer of 1 or more. n_{B} is preferably up to 5 and more preferably up to 3 in terms of the cost although the upper limit is not particularly limited.

The inkjet ink preferably contains the solvents A more than the solvents B on the weight basis. In other words, the weight ratio of the solvents A to the solvents B in the inkjet ink (weight of the solvents A/weight of the solvents B) is preferably more than 1.

The weight ratio is more preferably at least 2 in terms of the compatibility between the stability in continuous discharge and the surface state of the polymer film during the drawing. In general, the upper limit of the weight ratio is preferably up to 20 and more preferably up to 10.

In a preferred embodiment, the solvent B is a polymerizable solvent (polymerizable liquid) in terms of the improved surface state of the polymer film during the drawing. The polymerizable solvent (solvent having a polymerizable group) desirably has a molecular weight comparatively as low as 300 or less and a functionality of 2 or less at which the solubility of the polymer components is high, and the solvent preferably has a functional group (group represented by W in formula (1)) capable of forming an interaction with the plating catalyst or its precursor.

More specifically, the solvent B is preferably a (meth)acrylate or a (meth)acrylamide containing nitrogen-containing functional groups such as imide group, pyridine group, tertiary amino group, ammonium group, pyrrolidone group, amidino group, triazine group, triazole group, benzotriazole group, benzimidazole group, quinoline group, pyrimidine group, pyrazine group, nazoline group, quinoxaline group, purine group, triazine group, piperidine group, piperazine group, pyrrolidine group, pyrazole group, aniline group, alkylamine group structure-containing group, isocyanuric structure-containing group, nitro group, nitroso group, azo group, diazo group, azide group, cyano group, and cyanate group (R—O—CN); ether group, carbonyl group, ester group, N-oxide structure-containing group, S-oxide structure-containing group, N-hydroxy structure-containing group, phenolic hydroxyl group, or hydroxyl group.

[Inkjet Ink]

The inkjet ink of the invention contains the polymer and at least one solvent. The inkjet ink may be used in various applications such as coating ink but is preferably used to form the polymer layer which receives the plating catalyst or its precursor. In other words, the inkjet ink is preferably used as the inkjet ink for forming the polymer layer.

The content of the polymer in the inkjet ink is not particularly limited and is preferably from 0.5 to 25 wt %, more preferably from 1 to 20 wt % and even more preferably from 4 to 15 wt % with respect to the total ink amount in terms of more excellent stability in continuous discharge.

The content of the solvent(s) in the inkjet ink is not particularly limited and is preferably from 70 to 99 wt % and more preferably from 80 to 99 wt % and even more preferably from 85 to 96 wt % with respect to the total ink amount in terms of more excellent stability in continuous discharge.

(Optional Component)

The inkjet ink of the invention may contain additives such as surfactant and radical generator as long as the effects of the invention are not impaired.

(Surfactant)

The inkjet ink of the invention may further contain a surfactant. The surfactant is preferably contained in terms of the stability in inkjet discharge and leveling properties in ink deposition.

Examples of the surfactant include a nonionic surfactant, an ampholytic surfactant, an anionic surfactant containing ammonium ion as the counterion, and a cationic surfactant containing an organic acid anion as the counterion. Examples of the nonionic surfactant include polyethylene glycol derivatives and polypropylene glycol derivatives. Examples of the ampholytic surfactant include long-chain alkyl betaines. Examples of the anionic surfactant containing ammonium ion as the counterion include ammonium salts of long-chain alkyl sulfuric acids, ammonium salts of alkylaryl sulfuric acids, ammonium salts of alkylaryl sulfonic acids, ammonium salts of alkyl phosphoric acids, and ammonium salts of polycarboxylic acid polymers.

The content of the surfactant in the inkjet ink is not particularly limited and is preferably at least 0 wt % but not more than 5 wt %, and more preferably 0.01 to 2 wt % with respect to the total ink amount. The surfactant content within the above-defined range is preferred because a preferred surface tension is obtained without deteriorating other physical properties of the ink.

(Radical Generator)

The inkjet ink of the invention may contain a radical generator (polymerization initiator) in order to promote the reaction of the polymerizable group in the polymer. The radical generator may be selected as appropriate for the type of polymer and examples thereof include a photo radical generator and a heat radical generator.

At least one selected from the group consisting of oxime esters, acylphosphine oxides, α-hydroxyalkylketones, lophine dimers, and trihalomethyl triazines is preferred.

The content of the radical generator is preferably from 0 to 5 wt %, more preferably from 0.1 to 5 wt % and even more preferably form 0.5 to 3 wt % with respect to the total ink amount. At a radical generator content within the above-defined range, a better sensitivity and stronger curing can be achieved.

(Method of Manufacturing Inkjet Ink)

A known inkjet ink-manufacturing method can be applied to manufacture the inkjet ink of the invention. The inkjet ink may be prepared by dissolving optional components such as surfactant and radical generator in a solvent after the dissolution of the polymer therein.

[Physical Property Value of Inkjet Ink]

The physical property value of the inkjet ink of the invention is not particularly limited as long as the inkjet ink can be discharged from the inkjet head. The inkjet ink preferably has an ink viscosity at 25° C. of 50 mPa·s or less, more preferably 2 to 20 mPa·s and most preferably 2 to 15 mPa·s in terms of the discharge stability. In the case of discharge using a device, the inkjet ink is preferably kept at an approximately constant temperature within a range of 20 to 80° C. and the viscosity is more preferably up to 20 mPa·s at the temperatures within the foregoing range. In a device set at a high temperature, the ink viscosity is decreased to enable discharge of ink with a higher viscosity. However, elevated temperatures may cause alteration of ink due to heat, a thermal polymerization reaction in the head and evaporation of the solvent on the surface of the nozzle through which the ink is discharged, whereby the nozzle is easily clogged. Therefore, the temperature is preferably up to 50° C.

The viscosity is measured with a commonly used E-type viscosimeter (e.g., E-type viscosimeter RE-80L available from Toki Sangyo Co., Ltd.).

The inkjet ink has a surface tension (static surface tension) at 25° C. of 20 to 40 mN/m and more preferably 20 to 35 mN/m in terms of improved wettability with respect to an impermeable substrate and discharge stability.

The surface tension is measured by the Wilhelmy method at a solution temperature of 25° C. and 60% RH with a commonly used surface tensiometer (e.g., FACE SURFACE TENSIOMETER CBVB-A3 available from Kyowa Interface Science Co., Ltd.).

[Surface Metal Film Material and Its Manufacturing Method]

Next, the method of manufacturing a surface metal film material using the inkjet ink of the invention is described. The inventive manufacturing method of the surface metal film material is not particularly limited and the surface metal film material is preferably manufactured by the following steps (1) to (3):

(1) A layer-forming step which includes applying or discharging the inkjet ink onto a substrate by an inkjet system and curing the applied or discharged ink by heating or by exposure to light to form a polymer layer;
(2) a catalyst applying step which includes applying a plating catalyst or its precursor to the polymer layer; and
(3) a plating step which includes performing plating to form a metal film on the polymer layer.

The step (1) is preferably performed by direct chemical bonding of the polymer to the substrate.

The respective steps are described below.

[Layer-Forming Step]

This step includes applying the inkjet ink onto the substrate by an inkjet system and curing the applied ink. In a preferred embodiment of this step, the polymer in the polymer layer is directly bonded to the substrate via the polymerizable group.

In the inkjet system, picoliter-order liquid droplets are discharged from the liquid discharge nozzles onto the substrate in accordance with recording signals (digital data) to form a pattern. This is a method which is excellent in forming micropatterns.

The inkjet system used in this step is not particularly limited and conventionally known various methods may be employed as exemplified by a method in which charged inkjet ink is continuously discharged and controlled by the electric field, a method in which a piezoelectric element is used to discharge the inkjet ink intermittently, and a method in which bubbles generated by heating the inkjet ink are used to discharge the ink intermittently. In other words, inkjet drawing may be performed by any conventionally known system such as piezoelectric inkjet system or thermal inkjet system. In addition, not only a conventional inkjet drawing device but also a drawing device equipped with a heater may be used.

Various types of inkjet heads (discharge heads) may be used as exemplified by continuous or on-demand piezoelectric, thermal, solid and electrostatic attraction systems. The discharge portions (nozzles) of the inkjet head are not limited to be of a single-row arrangement but may be disposed in a plurality of rows or in a houndstooth check pattern.

The inkjet system is used to deposit or discharge the ink of the invention on a place of the substrate where the polymer layer is to be formed. The ink may be deposited on whole the surface of the substrate or in a desired pattern.

The solvent is removed after the ink discharge and therefore drying treatment may optionally be performed. The drying treatment may also be performed with a hot plate or an electric furnace or by lamp annealing.

(Heating or Exposure to Light)

Next, the ink deposited on the substrate is cured by heating or by exposure to light. The ink is preferably exposed to light in terms of easily forming a pattern image.

Irradiation with light from a UV lamp or with visible light is used for exposure. Exemplary light sources include mercury lamp, metal halide lamp, xenon lamp, chemical lamp, and carbon arc lamp. Examples of the radiation include electron rays, X-rays, ion beams and far infrared rays, and g-line rays, i-line rays, deep UV rays, and high-density energy beams (laser beams) may also be used.

Preferred examples include exposure scanning with an infrared laser, high-intensity flash exposure with a xenon discharge lamp and exposure with an infrared lamp. The exposure time varies with the reactivity of the polymer and the light source used and is typically from 10 seconds to 5 hours. The exposure energy is selected as appropriate for the material used and is preferably from 30 to 1,500 mW/cm².

In the case of heating, an air dryer, an oven, an infrared dryer or a heating drum may be used. The temperature condition is not particularly limited and the ink is typically heated at 100 to 300° C. for 5 to 120 minutes.

As a result of energy application by heating or exposure, a polymer curing reaction only takes place in the region where the ink was applied.

The thickness of the polymer layer formed is not particularly limited and is preferably more than 0.1 μm but up to 10 μm and more preferably from 0.3 to 5 μm in terms of more excellent adhesion to the metal film.

(Substrate)

The substrate that may be used in this step should have shape retaining properties and preferably has the function of chemical bonding between the polymer and the substrate surface. More specifically, the substrate itself can generate radicals upon exposure or be composed of a support and an intermediate layer (e.g., adhesion promoting layer) which was formed on the support and can generate radicals upon exposure.

(Support, Substrate)

The support that may be used in the invention is preferably a dimensionally stable sheet and examples thereof include paper; paper laminated with plastic materials such as polyethylene, polypropylene and polystyrene; metal sheets made of, for example, aluminum, zinc and copper; plastic films made of, for example, cellulose diacetate, cellulose triacetate, cellulose propionate, cellulose butyrate, cellulose acetate, cellulose nitrate, polyethylene terephthalate, polyethylene, polystyrene, polypropylene, polycarbonate, polyvinyl acetal, polyimide, epoxy, bismaleimide resin, polyphenylene oxide, liquid crystal polymer, and polytetrafluoroethylene; and paper or plastic films on which any of the foregoing metals is laminated or vapor-deposited. The support that may be used in the invention is preferably made of an epoxy resin or a polyimide resin.

If these supports have the function of forming direct chemical bonding with the polymer at their surfaces, the support may be used as the substrate.

The patterned metal material obtained by the method of manufacturing the patterned metal material of the invention may be applied to semiconductor packages and various electrical circuit boards. Insulating resin-containing substrates, and more specifically substrates made of insulating resins and substrates having a support and an insulating resin layer formed thereon are preferably used in such applications.

Known insulating resin compositions are used to obtain a substrate made of an insulating resin or an insulating resin layer. In addition to the main resin, such insulating resin compositions may further contain various additives according to the intended purposes. For example, a polyfunctional acrylate monomer is added to enhance the strength of the insulating layer, inorganic or organic particles are added to enhance the strength of the insulating layer and improve the electrical properties, and other means can be applied.

The insulating resin as used herein refers to a resin having sufficient insulating properties to be used in known insulating films and insulating layer, and may be applied to the invention even if it is not a complete insulator as long as it has the insulating properties suitable to the purpose.

Exemplary insulating resins that may be used include those as described in paragraphs [0024] to [0025] of JP 2008-108791 A.

(Adhesion Promoting Layer)

The adhesion promoting layer to be described below may also be formed to improve the adhesion between the substrate and the polymer layer formed thereon. The adhesion promoting layer is an intermediate layer which ensures the adhesion between the substrate and the polymer layer. This layer may have an affinity for the substrate and the polymer layer. Alternatively, the layer may react with the polymer during the curing to form chemical bonding.

The adhesion promoting layer may be formed on each surface of the support if it is in a sheet form. The adhesion promoting layer preferably forms chemical bonding with the polymer during the curing upon irradiation with light. A photoinitiator is preferably introduced into the adhesion promoting layer which forms such chemical bonding. It is also preferred to form the adhesion promoting layer using an aqueous latex dispersion in terms of the workability.

Resin compositions having good adhesion to the support and compounds (radical generators) capable of generating radicals upon exposure are preferably used to form the adhesion promoting layer. In cases where the resin making up the resin composition has a radical-generating moiety, it is not necessary to separately add a compound capable of generating radicals.

In the adhesion promoting layer of the invention, in cases where the support is made of a known insulating resin having been used as a material of a multilayer laminate, a build-up substrate, or a flexible substrate, the insulating resin composition is also preferably used as the resin composition for use in forming the adhesion promoting layer in terms of the adhesion to the support.

An embodiment in which the support is made of an insulating resin and the adhesion promoting layer is made of an insulating resin composition is described below.

The insulating resin composition for use in forming the adhesion promoting layer may or may not contain the same resin as the electrical insulating resin making up the support but it is preferred to use a resin whose thermophysical properties such as glass transition point, modulus of elasticity and linear coefficient of expansion are close to those of the resin making up the support. More specifically, it is preferred to use, for example, the same type of insulating resin as that making up the support in terms of the adhesion.

In the invention, the insulating resin for use in the adhesion promoting layer refers to a resin having sufficient insulating properties to enable the use in known insulating films, and may be applied to the invention even if it is not a complete insulator as long as it has the insulating properties suitable to the purpose.

Specific examples of the insulating resin include a themosetting resin, a thermoplastic resin and a mixture thereof. Examples of the thermosetting resin include epoxy resins, phenol resins, polyimide resins, polyester resins, bismaleimide resins, polyolefin resins, and isocyanate resins. Examples of the thermoplastic resin include phenoxy resins, polyethersulfone, polysulfone, polyphenylene sulfone, polyphenylene sulfide, polyphenyl ether, polyetherimide and ABS resins.

The thermoplastic resins and thermosetting resins may be used alone or in combination of two or more.

A resin having a skeleton which may generate active points where the resin may form an interaction with the polymer may also be used as the insulating resin for use in the adhesion promoting layer.

A polymer latex may be used to form the adhesion promoting layer. The polymer latex is a dispersion of water-insoluble particulate polymer in water.

Various additives (substances such as rubber and SBR latex, a binder for improving the film properties, a plasticizer, a surfactant, a viscosity modifier, a colorant, a flame retardant, a tackifier, a silane coupling agent, an antioxidant, a UV absorber) may be optionally added to the adhesion promoting layer of the invention.

As described above, the adhesion promoting layer preferably contains the resin composition and the compound (radical generator) capable of generating radicals upon exposure. A conventionally known photopolymerization initiator is used as the compound capable of generating radicals upon exposure.

Specific examples of the photopolymerization initiator include acetophenones such as p-tert-butyl trichloroacetophenone; ketones such as 4,4′-bis(dimethylamino)benzophenone and 2-ethylthioxanthone; benzoin ethers such as benzoin isopropyl ether; benzyl ketals such as benzyl dimethyl ketal; sulfonium salts such as triphenylsulfonium chloride; and iodonium salts such as diphenyliodonium chloride.

The adhesion promoting layer generally has a thickness of 0.1 μm to 10 μm and preferably 0.2 μm to 5 μm. If the adhesion promoting layer formed has a thickness within the above-described general range, the adhesion promoting layer has sufficient strength in the adhesion to the adjoining support and the polymer layer.

The adhesion promoting layer preferably has a surface roughness R_{z} as measured by the 10-point mean roughness method according to JIS B 0601 (1994) of up to 500 nm and more preferably up to 100 nm in order to improve the physical properties of the plated metal film to be formed. When the surface roughness of the adhesion promoting layer is within the above-defined range, that is, the adhesion promoting layer is highly smooth, the adhesion promoting layer is advantageously used to manufacture ultra-fine printed circuit boards including, for example, a circuit pattern with a line width of up to 25 μm and a line-to-line space of up to 25 μm.

The adhesion promoting layer is formed on the surface of the support by any known layer forming methods such as coating, transfer and printing. The adhesion promoting layer may be patterned as desired by printing or development.

[Catalyst Applying Step]

This step applies a plating catalyst or its precursor to the polymer layer formed in the previous step (catalyst applying step). In this step, according to the function of the interactive group, the applied plating catalyst or its precursor adheres or adsorbs to the interactive group the graft polymer making up the polymer layer has.

The materials which serve as the plating catalyst or electrode in the plating step to be described later are used for the plating catalyst or its precursor. Therefore, the plating catalyst or its precursor is determined according to the type of plating used in the plating step.

The plating catalyst or its precursor that may be used in this step is preferably an electroless plating catalyst or its precursor.

(Electroless Plating Catalyst)

Any electroless plating catalyst may be used in the invention as long as it serves as the active nucleus during the electroless plating. More specifically, a metal which is capable of catalyzing the autocatalytic reduction reaction and which is known as a metal capable of electroless plating with lower ionization tendency than Ni may be used. Specific examples thereof include Pd, Ag, Cu, Ni, Al, Fe and Co. Of these, metals capable of multidentate coordination are preferred and Pd is most preferred in terms of the number of types of functional group capable of coordination and the high catalytic ability.

The electroless plating catalyst may be used as a metallic colloid. In general, the metallic colloid can be prepared by reducing metal ions in a solution containing a charged surfactant or a charged protective agent. The charge of the metallic colloid can be adjusted by the surfactant or protective agent used.

(Electroless Plating Catalyst Precursor)

The electroless plating catalyst precursor can be used in this step without any particular limitation as long as it may serve as the electroless plating catalyst through a chemical reaction. Metal ions of the metals illustrated above for the electroless plating catalyst are mainly used. The metal ions which are the electroless plating catalyst precursors are turned through the reduction reaction into zero-valent metals as the electroless plating catalysts. After the metal ion as the electroless plating catalyst precursor is applied to the polymer layer, the electroless plating precursor may be separately turned into a zero-valent metal as the electroless plating catalyst through the reduction reaction before being immersed in the electroless plating bath. Alternatively, the electroless plating catalyst precursor may be immersed into the electroless plating bath without any treatment to be turned into a metal (electroless plating catalyst) by the action of the reducing agent in the electroless plating bath.

Actually, the metal ion as the electroless plating precursor is applied to the polymer layer by the use of a metal salt. The metal salt used is not particularly limited as long as it dissolves in a suitable solvent to dissociate into a metal ion and a base (anion). Examples thereof include M(NO₃)ₙ, MCln, M_{2/n}(SO₄) and M_{3/n}(PO₄)Pd(OAc)ₙ (M represents a n-valent metal atom). The metal ion resulting from the dissociation of the metal salt may be advantageously used. Specific examples of the metal ion include Ag ion, Cu ion, Al ion, Ni ion, Co ion, Fe ion, and Pd ion. Among these, those capable of multidentate coordination are preferred. Pd ion is particularly preferred in terms of the number of types of functional group capable of coordination and the catalytic ability.

An example of the plating catalyst or its precursor that may be preferably used in the invention includes a palladium compound. The palladium compound serves as an active nucleus during the plating treatment to deposit the metal and functions as the plating catalyst (palladium) or its precursor (palladium ion). The palladium compound is not particularly limited as long as it contains palladium and serves as the nucleus during the plating treatment. Examples thereof include a palladium salt, a palladium (0) complex and a palladium colloid.

A method of applying a metal as the plating catalyst or a metal salt as the plating precursor to the polymer layer involves preparing a dispersion of the metal in a suitable dispersion medium or a solution of the metal salt dissociated into a metal ion in a suitable solvent, and applying the dispersion or the solution to the polymer layer or immersing the substrate having the polymer layer formed thereon into the dispersion or the solution.

The polymer layer which contains the polymer having an interactive group and directly chemically bonded to the substrate and the plating catalyst or its precursor can be formed by contacting the composition containing the polymer of the invention and the plating catalyst or its precursor with the substrate and applying predetermined energy under heating or exposure. This method enables the layer-forming step and the catalyst applying step to be performed in a single step.

By contacting the plating catalyst or its precursor with the polymer as described above, the plating catalyst or its precursor can be adsorbed onto the interactive group included in the polymer layer by means of the interaction based on the intermolecular force such as van der Waals force or the interaction based on the coordination bond using lone-pair electrons.

In terms of sufficient adsorption, the metal concentration in the dispersion, solution or composition or the metal ion concentration in the solution is preferably from 0.001 to 50 wt %, and more preferably from 0.005 to 30 wt %. The contact time is preferably from about 30 seconds to about 24 hours and more preferably from about 1 minute to about 1 hour.

(Organic Solvent)

The solution containing the plating catalyst or its precursor (plating catalyst solution) may contain an organic solvent. The organic solvent contained contributes to improving the permeability of the polymer layer with respect to the plating catalyst or its precursor, whereby the plating catalyst or its precursor can be efficiently adsorbed onto the interactive group.

The solvent that may be used to prepare the plating catalyst solution is not particularly limited as long as it permeates the polymer layer. Since water is commonly used as the main solvent (dispersion medium) of the plating catalyst solution, aqueous organic solvents as described below in detail are preferred.

(Aqueous Organic Solvent)

The aqueous organic solvent is not particularly limited as long as at least 1 wt % of the solvent dissolves in water. Examples of the aqueous organic solvent include a ketone solvent, an ester solvent, an alcohol solvent, an ether solvent, an amine solvent, a thiol solvent and a halogen solvent.

(Other Catalysts)

When the polymer layer is directly electroplated without performing electroless plating in the plating step to be described later, a zero-valent metal may be used in the invention as the catalyst. Examples of the zero-valent metal include Pd, Ag, Cu, Ni, Al, Fe and Co. Among these, metals capable of multidentate coordination are preferred. Pd, Ag and Cu are particularly preferred in terms of their superior adsorptivity (attachability) to the interactive group (such as a cyano group) and high catalytic ability.

By performing the catalyst applying step as described above, an interaction can be formed between the interactive group in the polymer layer and the plating catalyst or its precursor. The polymer layer to which the plating catalyst is applied is used as the plating receptive layer to be subjected to plating treatment.

[Plating Step]

This step forms a plated film (metal film) by plating the polymer layer to which the plating catalyst or its precursor is applied. The thus formed plated film has good electrical conductivity and good adhesion to the polymer layer.

Exemplary types of plating performed in this step include electroless plating and electroplating. The type of plating can be selected as appropriate for the function of the plating catalyst or its precursor which formed an interaction with the polymer layer in the catalyst applying step. In other words, in this step, the polymer layer to which the plating catalyst or its precursor was applied may be subjected to electroplating or electroless plating.

Electroless plating is particularly preferred in the invention in terms of the formability of a hybrid structure in the polymer layer and improved adhesion. In a more preferred embodiment, electroless plating is followed by electroplating in order to obtain a plated layer with a desired thickness. The plating treatment advantageously performed in this step is described below.

(Electroless Plating)

Electroless plating refers to an operation in which a metal is deposited by a chemical reaction using a solution containing metal ions to be deposited by plating.

Electroless plating in this step is performed by, for example, washing the substrate to which the electroless plating catalyst has been applied with water to remove an excessive amount of electroless plating catalyst (metal), and then immersing the substrate in an electroless plating bath. A commonly known electroless plating bath can be used for the electroless plating.

In cases where the substrate to which the electroless plating catalyst precursor has been applied so as to be adsorbed onto or impregnated in the polymer layer is immersed in the electroless plating bath, the substrate is washed with water to remove an excessive amount of the precursor (metal salt or the like) prior to the immersion in the electroless plating bath. In this case, reduction of the plating catalyst precursor and the subsequent electroless plating are performed in the electroless plating bath. In this case, a commonly known electroless plating bath may also be used as the electroless plating bath.

Instead of the embodiment using the above-described electroless plating solution, reduction of the electroless plating catalyst precursor may be performed as a separate step preceding the electroless plating by preparing a catalyst activating solution (reducing solution). The catalyst activating solution is a solution containing a reducing agent which can reduce the electroless plating catalyst precursor (typically a metal ion) to a zero-valent metal, and the concentration of the reducing agent is from 0.1 wt % to 50 wt % and preferably from 1 wt % to 30 wt % with respect to the total solution amount. Examples of the reducing agent that may be used include boron-based reducing agents such as sodium borohydride and dimethylamine borane, formaldehyde and hypophosphorous acid.

In addition to the solvent, the composition of the electroless plating bath generally includes, as main components, (1) a metal ion for plating, (2) a reducing agent, and (3) an additive enhancing the stability of the metal ion (stabilizer). The electroless plating bath may further contain known additives.

The organic solvent that may be used in the plating bath is to be soluble in water and in view of this, ketones such as acetone, and alcohols such as methanol, ethanol and isopropanol are preferably used.

Copper, tin, lead, nickel, gold, palladium and rhodium are known metals that may be used in the electroless plating bath. Of these, copper and gold are particularly preferred in terms of electrical conductivity.

A reducing agent and additives are selected as appropriate for the metal used. For example, the copper electroless plating bath contains CuSO₄ as the copper salt, HCOH as the reducing agent, and a chelating agent that serves as a copper ion stabilizer such as EDTA or Rochelle salt, and trialkanolamine. The plating bath used for CoNiP electroless plating contains cobalt sulfate or nickel sulfate as the metal salt, sodium hypophosphite as the reducing agent, and sodium malonate, sodium malate or sodium succinate as the complexing agent. The palladium electroless plating bath contains (Pd(NH₃)₄)Cl₂ as the metal ion, NH₃ or H₂NNH₂ as the reducing agent, and EDTA as the stabilizer. These plating baths may also contain components other than the above.

The thickness of the film (metal film) plated by the electroless plating may be controlled by adjusting the metal ion concentration in the plating bath, the immersion time in the plating bath, and the temperature of the plating bath. The plated film preferably has a thickness of 0.2 μm to 2.0 μm in terms of electrical conductivity and adhesion.

The immersion time in the plating bath is preferably from about 1 minute to about 6 hours and more preferably from about 1 minute to about 3 hours.

The cross-section of the plated film obtained as above by electroless plating was observed by a scanning electron microscope (SEM) and it was confirmed that the electroless plating catalyst and the particulate plated metal were densely dispersed in the polymer and the plated metal was further deposited on the polymer layer. Since the interface between the substrate and the plated film is in a hybrid state of the polymer and the microparticles, good adhesion is achieved even when the interface between the substrate (organic component) and the inorganic substance (catalyst metal or plated metal) is flat and smooth (for example, the roughness is 500 nm or less).

(Electroplating)

In this step, in cases where the plating catalyst or its precursor that has been applied in the catalyst applying step functions as an electrode, the polymer layer to which the catalyst or its precursor has been applied may be electroplated.

The foregoing electroless plating may be followed by electroplating using the plated film as the electrode. In this way, a new metal film with a desired thickness can be easily formed based on the film formed by electroless plating and having good adhesion to the substrate. A metal film with a thickness suitable to the intended purpose can be formed by electroplating following electroless plating and therefore the metal film of the invention can be advantageously used in various applications.

According to the invention, electroplating may be performed by a conventionally known method. Examples of the metal that may be used in electroplating in this step include copper, chromium, lead, nickel, gold, silver, tin, and zinc. In terms of electrical conductivity, copper, gold and silver are preferred and copper is more preferred.

The thickness of the metal film obtained by electroplating may vary with the intended use and can be controlled by adjusting the concentration of the metal contained in the plating bath, current density or the like. When used in general electrical wiring, the film thickness is preferably from 1.0 μm to 30 μm in terms of electrical conductivity.

In the invention, a metal or a metal salt derived from the foregoing plating catalyst or its precursor, and/or a metal deposited in the polymer layer by electroless plating is formed in the layer as a fractal microstructure, whereby the adhesion between the metal film and the polymer layer can be further improved.

[Surface Metal Film Material]

The surface metal film material of the invention can be obtained by performing the respective steps of the method of manufacturing the surface metal film material of the invention.

The surface metal film material obtained by the method of manufacturing the surface metal film material of the invention has the effect that the adhesion force of the metal film has few variations even under high temperature and high humidity conditions. The surface metal film material may be used in various applications such as electromagnetic wave protecting films, coating films, two-layer copper clad laminate (CCL) materials, electric wiring materials and decorative materials.

[Patterned Metal Material and its Manufacturing Method]

A patterned metal material can be manufactured by performing the step of pattern-etching the metal film in the surface metal film material. In other words, the metal film (plated film) in the surface metal film material of the invention can be patterned to obtain wiring (metal pattern).

The etching step is described below in detail.

[Etching Step]

This is a step for pattern-etching the metal film (plated film) formed in the plating step. In other words, in this step, unnecessary portions of the metal film formed on the whole surface of the substrate can be removed by etching to form a desired metal pattern.

Any process may be used to form the metal pattern and more specifically commonly known processes such as subtractive process and semi-additive process are used.

The subtractive process is a process which involves forming a dry film resist layer on the formed metal film, subjecting the dry film resist layer to pattern-exposure and development to form the same pattern as in the metal pattern portion and removing the metal film with an etching solution while masking the dry film resist pattern to form a metal pattern. Any material may be used for the dry film resist as exemplified by negative type, positive type, liquid type and film type. Etching techniques commonly used in the manufacture of printed circuit boards may be used as exemplified by wet etching and dry etching, and a suitable technique can be selected. Wet etching is preferred because the device is simple to handle. For example, an aqueous solution of cupric chloride or ferric chloride may be used as the etching solution.

The semi-additive process is a process which involves forming a dry film resist layer on the formed metal film, subjecting the dry film resist layer to pattern-exposure and development to form the same pattern as in non-metal pattern portion, performing electroplating while masking the dry film resist pattern, removing the dry film resist pattern and performing quick etching to remove the metal film in a pattern shape to form a metal pattern. The same materials as used in the subtractive process may be used for the dry film resist and etching solution. The foregoing process may be used for electroplating.

A patterned metal material having a desired metal pattern is manufactured by performing the foregoing steps.

The patterned metal material may also be manufactured by forming the polymer layer in a pattern shape in the layer-forming step and subjecting the patterned polymer layer to the catalyst applying step and the plating step.

The polymer layer may be formed in the pattern shape in the layer-forming step, for example, by a method which involves discharging the ink onto the substrate in a pattern shape by an inkjet system and curing the ink by heating or exposure to light.

[Patterned Metal Material]

The polymer layer making up the patterned metal material of the invention has low water absorbability and high hydrophobicity and therefore the exposed areas of the polymer layer (areas where no metal pattern is formed) have excellent insulation reliability.

The patterned metal material of the invention preferably has the metal film (plated film) on the whole surface or local areas of the substrate (or on the roughened surface of the adhesion promoting layer if it is formed) which has a surface roughness of up to 500 nm and more preferably up to 100 nm. The adhesion force between the substrate and the metal pattern is preferably at least 0.2 kN/m. In other words, the patterned metal material is characterized in that the adhesion between the substrate and the metal pattern is excellent although the substrate has a smooth surface.

The substrate is cut vertically to its surface and the cross section is observed by SEM to measure the surface roughness of the substrate.

More specifically, the surface roughness R_{z} measured according to JIS B 0601 is preferably up to 500 nm in terms of the difference between the average value of the top five peak Z data and the average of the top five valley Z data.

The adhesion between the substrate and the metal film is determined by a method which involves adhering a copper sheet with a thickness of 0.1 mm to the surface of the metal film (metal pattern) with an epoxy adhesive Araldite (Ciba-Geigy Ltd.), drying the adhesive at 140° C. for 4 hours and conducting a 90-degree peel test according to JIS C 6481, or a method which involves directly peeling off the end of the metal film itself to conduct a 90-degree peel test according to JIS C 6481.

[Circuit Board]

The patterned metal material obtained by the patterned metal material-manufacturing method of the invention may be used in various applications including semiconductor chips, various electrical circuit boards, FPC, COF, TAB, antennas, multilayer circuit boards and mother boards.

Of these, the circuit board with metal pattern interconnects manufactured by the method of manufacturing the patterned metal material of the invention can form interconnects with excellent adhesion to the smooth substrate and has excellent radio frequency characteristics, and exhibits excellent interconnect insulation reliability even in a high-density micro wiring.

In cases where the circuit board of the invention is configured as a multilayer circuit board, an insulating resin layer (interlayer dielectric film) may be further formed on the surface of the patterned metal material and further interconnects (metal pattern) may be formed on the surface thereof. Alternatively, a solder resist may be formed on the surface of the patterned metal material.

The interlayer dielectric film that may be used in the invention is made of, for example, epoxy resin, aramid resin, crystalline polyolefin resin, amorphous polyolefin resin, fluorine-containing resin, polyimide resin, polyethersulfone resin, polyphenylene sulfide resin, polyether ether ketone resin or liquid-crystal resin.

Of these, the interlayer dielectric film preferably contains epoxy resin, polyimide resin or liquid-crystal resin in terms of adhesion to the foregoing polymer layer, dimension stability, heat resistance and electrical insulating properties.

Known materials as described in detail in, for example, JP 10-204150 A and JP 2003-222993 A may be used for the solder resist that may be used to protect the wiring on the surface of the patterned metal material. Commercial products such as PFR800 and PSR4000 (Taiyo Ink Mfg. Co., Ltd.) and SR7200G (Hitachi Chemical Co., Ltd.) may be used for the solder resist.

### EXAMPLES

The invention is described below in further detail by way of examples. However, the invention should not be construed as being limited to the following examples. Unless otherwise specified, the weight ratio is expressed by percentage or parts by weight.

The weight-average molecular weight to be described later was measured by high performance GPC (HLC-8220GPC available from Tosoh Corporation) with the polymer dissolved in NMP. The molecular weight was calculated in terms of polystyrene. The structure of the polymer was identified by ¹H-NMR (Bruker, 400 MHz).

(Synthesis Example 1: Polymer P-1)

To a three-neck flask with a volume of 300 mL was added 20 g of diethylene glycol diacetate, which was heated to 75° C. in a nitrogen stream. A solution of 3.77 g of 2-hydroxyethyl methacrylate, 16.15 g of 2-cyanoethyl methacrylate and 0.0668 g of V-601 (Wako Pure Chemical Industries, Ltd.) in 20 g of diethylene glycol diacetate was added dropwise over 2.5 hours. After the dropwise addition, the reaction solution was heated to 80° C. and further stirred for 3 hours. Then, the reaction solution was cooled to room temperature.

To the reaction solution were added 0.15 g of di-tert-butylhydroquinone, 0.29 g of U-600 (Nitta Kasei Co., Ltd.), 8.82 g of Karenz AOI (Showa Denko K.K.) and 27.82 g of diethylene glycol diacetate and the mixture was reacted at 53° C. for 6 hours. Then, 1.86 g of methanol was added to the reaction solution and the mixture was reacted for another 1.5 hours. After the end of the reaction, the reaction solution was reprecipitated with water. The solid was recovered to obtain 10 g of Polymer P-1 with a weight-average molecular weight of 26,000. Numerical values in the chemical formula represent the molar percentage of the units (recurring units).

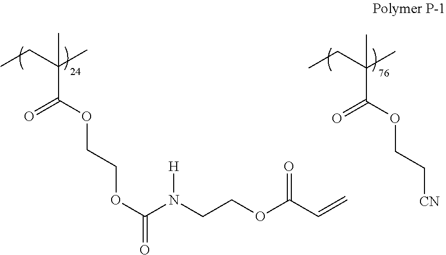

(Synthesis Example 2: Polymer P-2)

To a three-neck flask with a volume of 300 mL were added 73 g of tert-butylamine (Aldrich) and 7.3 g of water and the reaction solution was heated to 45° C. To the reaction solution was added dropwise 53 g of acrylonitrile (Wako Pure Chemical Industries, Ltd.). After the dropwise addition, the mixture was reacted for 3 hours and distilled off under reduced pressure to obtain 81 g of N-tert-butyl-cyanoethylamine.

Then, to a three-neck flask with a volume of 300 mL were added 80 g of the N-tert-butyl-cyanoethylamine and 500 g of ethyl acetate and the reaction solution was cooled to 5° C. To the reaction solution was added dropwise 43 g of acryloyl chloride (Tokyo Chemical Industry Co., Ltd.). After the dropwise addition, the reaction solution was returned to room temperature and was reacted for 3 hours. Then, the reactant was extracted with ethyl acetate and the ethyl acetate phase was washed with sodium bicarbonate water and brine and dried overnight with magnesium sulfate. Then, the ethyl acetate was evaporated to obtain a crude product. The crude product was recrystallized from isopropyl alcohol to obtain 44 g of N-tert-butyl-cyanoethyl acrylamide.

Then, 22 g of dimethyl carbonate was added to a three-neck flask with a volume 300 mL and heated to 65° C. in a nitrogen stream. A solution of 3.72 g of 2-hydroxyethyl acrylate (Tokyo Chemical Industry Co., Ltd.), 25.63 g of the N-tert-butyl-cyanoethyl acrylamide and 0.397 g of V-65 (Wako Pure Chemical Industries, Ltd.) in 22 g of dimethyl carbonate was added dropwise over 4 hours. After the dropwise addition, the reaction solution was further stirred for 3 hours and then cooled to room temperature.

To the reaction solution were added 0.093 g of TEMPO (Tokyo Chemical Industry Co., Ltd.), 0.277 g of U-600 (Nitto Kasei Co., Ltd.), 8.4 g of Karenz AOI (Showa Denko K.K.) and 8.4 g of dimethyl carbonate. The mixture was reacted at 45° C. for 6 hours. Then, to the reaction solution was added 1.1 g of water and the mixture was reacted for another 1.5 hours. After the end of the reaction, the reaction solution was reprecipitated with ethyl acetate/hexane (⅓). The solid was recovered to obtain 10 g of Polymer P-2 of the invention with a weight-average molecular weight of 23,000.

The structure of Polymer P-2 was identified by ¹H-NMR (Bruker, 400 MHz) with the polymer dissolved in d-DMSO and heated to 50° C. Numerical values in the chemical formula represent the molar percentage of the units (recurring units).

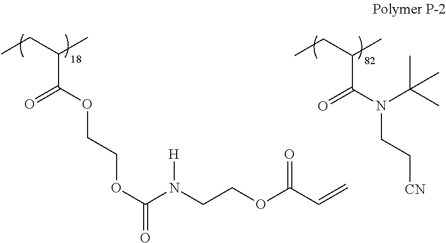

(Synthesis Example 3: Polymer P-3)

To a three-neck flask with a volume of 500 mL was added 9.4 g of N,N-dimethylacetamide, which was heated to 65° C. in a nitrogen stream. A solution of 5.8 g of 2-hydroxyethyl acrylate (Tokyo Chemical Industry Co., Ltd.), 3.8 g of acrylonitrile (Tokyo Chemical Industry Co., Ltd.), 9.0 g of acrylic acid (Tokyo Chemical Industry Co., Ltd.), and 0.5 g of V-65 (Wako Pure Chemical Industries, Ltd.) in 9.4 g of N,N-dimethylacetamide was added dropwise over 4 hours. After the dropwise addition, the reaction solution was further stirred for 3 hours. Then, 56 g of N,N-dimethylacetamide was added and the reaction solution was cooled to room temperature. To the reaction solution were added 17.6 g of Karenz MOI, 0.2 g of U-600 (Nitto Kasei Co., Ltd.) and 0.08 g of TEMPO (Tokyo Chemical Industry Co., Ltd.) and the mixture was heated to 45° C. and reacted for 6 hours. Then, 1.6 g of methanol was added to the reaction solution and the mixture was reacted for 1.5 hours. After the end of the reaction, the solid was collected by reprecipitation with water to obtain 14 g of Polymer P-3 with a weight-average molecular weight of 42,000. Numerical values in the chemical formula represent the molar percentage of the units (recurring units).

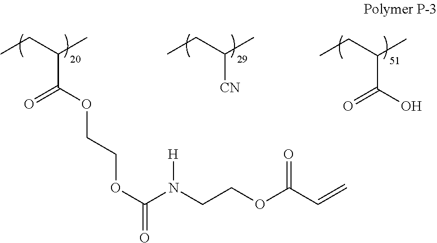

(Synthesis Example 4: Polymer P-4)

Polyacrylic acid (30 g; average molecular weight: 25,000) was dissolved in 200 mL of N,N-dimethylacetamide and to the solution were added 0.9 g of 2-ethyl-4-ethyl-imidazole, 50 mg of di-tert-pentylhydroquinone and 27 g of monomer A of the structure shown below. The mixture was reacted at 100° C. for 5 hours in a nitrogen stream.

Then, to a portion (50 g) of the reaction solution was added 11.6 mL of 4N NaOH in an ice bath. Thereafter, the solid was collected by reprecipitation with ethyl acetate, washed with water and dried to obtain Polymer P-4 with a weight-average molecular weight of 31,000. Numerical values in the chemical formula represent the molar percentage of the units (recurring units).

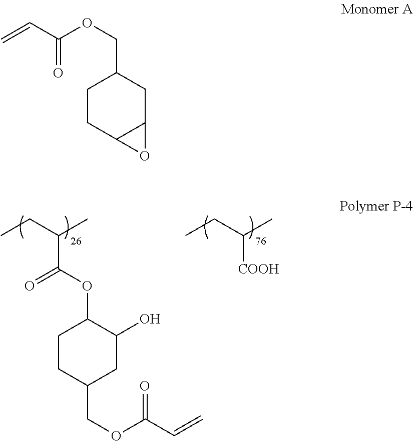

(Synthesis Example 5: Polymer P-5)

Polyacrylic acid (18 g; average molecular weight: 25,000) was dissolved in 300 g of DMAc (dimethylacetamide) and to the solution were added 0.41 g of hydroquinone, 19.4 g of 2-methacryloyloxyethyl isocyanate and 0.25 g of dibutyltin dilaurate. The mixture was reacted at 65° C. for 4 hours. The resulting polymer had an acid number of 7.02 meq/g. The carboxy group was neutralized with 1 mol/L aqueous sodium hydroxide and added to ethyl acetate to precipitate the polymer. The polymer was washed well to obtain Polymer P-5 with a weight-average molecular weight of 36,000. Numerical values in the chemical formula represent the molar percentage of the units (recurring units).

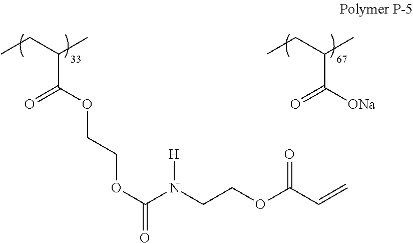

[Preparation of Inkjet Ink]

Polymers P-1 to P-5 synthesized as above were used to prepare inkjet inks according to the compositional ratio shown in Table 1.

The materials used to prepare the inks were shown below in detail.

### (Solvent)

2-Butanone (boiling point: 80° C.)
Acetonitrile (boiling point: 82° C.)
Ethyl lactate (boiling point: 154° C.)
Cyclohexanone (boiling point: 156° C.)
Dipropylene glycol dimethyl ether (boiling point: 175° C.)
Dipropylene glycol monomethyl ether acetate (boiling point: 213° C.)
Propylene carbonate (boiling point: 242° C.)
Triacetin (boiling point: 260° C.)
2-Cyanoethyl acrylate (boiling point: more than 300° C.)
Glycerol (boiling point: 290° C.)
Distilled water (boiling point: 100° C.)
Dimethyl sulfoxide (boiling point: 189° C.) (Surfactant)
BYK-323 (BYK Japan KK)
F-781F (DIC)

### (Polymerization Initiator)

IRGACURE379 (Ciba Specialty Chemicals Inc.)
IRGACURE819 (Ciba Specialty Chemicals Inc.)

[Measurement of Viscosity and Surface Tension]

The viscosity and surface tension of the inks prepared as above were measured. The ink viscosity was measured using an E-type viscosimeter (RE-80L from Toki Sangyo Co., Ltd.) under the following conditions while keeping the resulting inks at a temperature of 25° C. The results are shown in Table 1.

### (Measurement Conditions)

Rotor used: 1° 34′×R24

Measurement time: 2 minutes

Measurement temperature: 25° C.

The surface tension was measured using a surface tensiometer FACE SURFACE TENSIOMETER CBVB-A3 (Kyowa Interface Science Co., Ltd.) while keeping the resulting inks at a temperature of 25° C. The results are shown in Table 1.

The solvent boiling point in Table 1 is the average (T_{(b)}) of the solvent boiling points represented by formula (A):

TABLE 1
The numbers in the main components from the polymer to the polymerization
initiator are expressed by weight percentage.

| Component | Name | Ink 1 | Ink 2 | Ink 3 | Ink 4 | Ink 5 | Ink 6 | Ink 7 |
|---|---|---|---|---|---|---|---|---|
| Polymer | P-1 | 5 | 5 | — | — | — | 11 | — |
| | P-2 | — | — | 5 | — | — | — | — |
| | P-3 | — | — | — | 7.5 | 7.5 | — | — |
| | P-4 | — | — | — | — | — | — | 8 |
| | P-5 | — | — | — | — | — | — | — |
| Solvent (A) | 2-Butanone (b.p.: 80° C.) | — | — | — | 20 | — | — | — |
| | Acetonitrile (b.p.: 82° C.) | — | — | — | — | — | 25 | — |
| | Ethyl lactate (b.p.: 154° C.) | — | — | 86.8 | — | — | — | — |
| | Cyclohexanone (b.p.: 156° C.) | 79.95 | 29.95 | — | 55.9 | 75.9 | — | 79.85 |
| | Dipropylene glycol dimethyl | — | — | — | — | — | 37.45 | — |
| | ether (b.p.: 175° C.) | | | | | | | |
| | Distilled water (100) | — | — | — | — | — | — | — |
| Solvent (B) | Dimethyl sulfoxide | — | — | — | — | 15 | — | — |
| | (b.p.: 189° C.) | | | | | | | |
| | Dipropylene glycol monomethyl | 15 | 65 | — | — | — | — | 5 |
| | ether acetate (b.p.: 213° C. [symbol] | | | | | | | |
| | Propylene carbonate | — | — | 8 | — | — | — | 5 |
| | (b.p.: 242° C.) | | | | | | | |
| | Triacetin(b.p.: 260° C.) | — | — | — | 15 | — | — | — |
| | Glycerol(b.p.: 290° C.) | — | — | — | — | — | — | — |
| | 2-Cyanoethyl acrylate | — | — | — | — | — | 25 | — |
| | (b.p.: 330° C.) | | | | | | | |
| Surfactant | BYK-323 | 0.05 | 0.05 | — | 0.1 | 0.1 | — | — |
| | F-781F | — | — | 0.2 | — | — | 0.05 | 0.15 |
| Radical | IRGACURE 379 | — | — | — | — | — | 1.5 | 2 |
| generator | IRGACURE 819 | — | — | — | 1.5 | 1.5 | — | — |
| Physical | Solvent boiling point(° C.) | 165 | 195 | 161 | 156 | 161 | 184 | 164 |
| properties | Difference in solvent boiling | 57 | 57 | 88 | 120 | 33 | 192 | 72 |
| of solvent | point(° C.) *1 | | | | | | | |
| Physical | Ink viscosity (mP · s) | 8.2 | 8.4 | 7.8 | 10.2 | 9.7 | 11.4 | 9.1 |
| properties | Surface tension (mN/m) | 28.8 | 28.5 | 27.6 | 29.2 | 27.2 | 30.1 | 27.7 |
| of ink | | | | | | | | |

| | | | | | Compara- | Compara- | Compara- |
|---|---|---|---|---|---|---|---|
| | | | | | tive | tive | tive |
| Component | Name | Ink 8 | Ink 9 | Ink 10 | Ink 1 | Ink 2 | Ink 3 |
| Polymer | P-1 | — | — | — | 5 | — | — |
| | P-2 | 13 | — | — | — | — | — |
| | P-3 | — | 22 | — | — | 7.5 | — |
| | P-4 | — | — | — | — | — | — |
| | P-5 | — | — | 7.7 | — | — | 7.7 |
| Solvent (A) | 2-Butanone (b.p.: 80° C.) | 25 | 16.8 | — | 45 | 75.9 | — |
| | Acetonitrile (b.p.: 82° C.) | — | — | — | — | — | 30.7 |
| | Ethyl lactate (b.p.: 154° C.) | — | — | — | — | — | — |
| | Cyclohexanone (b.p.: 156° C.) | 50.9 | 47 | — | 4995 | — | — |
| | Dipropylene glycol dimethyl | — | — | — | — | — | — |
| | ether (b.p.: 175° C.) | | | | | | |
| | Distilled water (100) | — | — | 54.2 | — | — | 61.6 |
| Solvent (B) | Dimethyl sulfoxide | — | — | — | — | — | — |
| | (b.p.: 189° C.) | | | | | | |
| | Dipropylene glycol monomethyl | — | — | — | — | — | — |
| | ether acetate (b.p.: 213° C.#z,899 | | | | | | |
| | Propylene carbonate | — | — | — | — | — | — |
| | (b.p.: 242° C.) | | | | | | |
| | Triacetin(b.p.: 260° C.) | — | 12.6 | — | — | 15 | — |
| | Glycerol(b.p.: 290° C.) | — | — | 38 | — | — | — |
| | 2-Cyanoethyl acrylate | 10 | — | — | — | — | — |
| | (b.p.: 330° C.) | | | | | | |
| Surfactant | BYK-323 | 0.1 | 0.1 | 0.1 | 0.05 | 0.1 | — |
| | F-781F | — | — | — | — | — | — |
| Radical | IRGACURE 379 | — | — | — | — | — | — |
| generator | IRGACURE 819 | 1 | 1.5 | — | — | 1.5 | — |
| Physical | Solvent boiling point(° C.) | 151 | 156 | 178 | 120 | 110 | 94 |
| properties | Difference in solvent boiling | 199 | 124 | 190 | — | 180 | — |
| of solvent | point(° C.) *1 | | | | | | |
| Physical | Ink viscosity (mP · s) | 12.2 | 14.1 | 10.1 | 7.8 | 10.5 | 9.8 |
| properties | Surface tension (mN/m) | 27.9 | 27.8 | 29.9 | 28.4 | 29.8 | 42.4 |
| of ink | | | | | | | |

*1: Boiling point of solvent B - boiling point of solvent A (when two or more types of solvent A (or solvent B) are used, the boiling point of solvent A (or solvent B) is calculated by formula (B) (or formula C)). [symbol]
indicates data missing or illegible when filed

[Continuous Discharge Stability]

The inks prepared as above were used to evaluate the continuous discharge stability according to the method described below.

More specifically, each ink was discharged at a frequency of 4 kHz from 10 nozzles of an inkjet printer DMP-2831 (FUJIFILM Dimatix, Inc.) and the inks were rated as “excellent” when discharge from all of the 10 nozzles was made without abnormalities after 20 minutes, “good” when ink did not discharge from 1 or 2 nozzles or ink from 1 or 2 nozzles curved during the discharge, “fair” when ink did not discharge from 3 to 5 nozzles or ink from 3 to 5 nozzles curved during the discharge, and “poor” when ink did not discharge from 6 or more nozzles or ink from 6 or more nozzles curved during the discharge, or discharge from all the nozzles could not be started. The results are shown in Table 2.

[Polymer Patternability]

The inks prepared as above were used to evaluate the polymer patternability according the method described below.

Each ink was discharged from the nozzles of an inkjet printer DMP-2831 (FUJIFILM Dimatix, Inc.) to draw a linear pattern with a length of 5 cm and three line widths of 100 μm, 70 μm and 40 μm, and the drying step and the exposure step were performed. The inks were rated “good” when the polymer pattern did not disconnect, “fair” when no disconnection was observed but the line width increased by a factor of at least 1.3 but less than 2, and “poor” when the polymer pattern disconnected or when the line width increased by a factor of at least 2 and the length decreased.

In addition to the linear pattern, a 10 mm square (10 mm×10 mm) solid pattern was also drawn and the inks were rated “good” when the drawn image substantially had a predetermined size, “fair” when the droplets spread out to increase the width by a factor of at least 1.3 but less than 2, or when the droplets swelled slightly to decrease the width to at least one-half bur less than eight-tens, and “poor” when the ink considerably spread out to increase the width by a factor of at least 2 or when the droplets swelled slightly to decrease the width to less than one-half.

It is necessary for the criterion “poor” not to be included in the evaluation of the patternability.

The drying step was performed at 80° C. for 5 minutes. The exposure step was performed with an exposure device U-0272 (GS Yuasa Corporation) using a metal halide light source. The cumulative amount of light in the whole emission wavelength range was 2,000 mJ/cm². The results are shown in Table 2.

TABLE 2

| | | | | | | | | | | | Compara- | Compara- | Compara- |
|---|---|---|---|---|---|---|---|---|---|---|---|---|---|
| | | | | | | | | | | | tive | tive | tive |
| Evaluation method | Ink 1 | Ink 2 | Ink 3 | Ink 4 | Ink 5 | Ink 6 | Ink 7 | Ink 8 | Ink 9 | Ink 10 | Ink 1 | Ink 2 | Ink 3 |
| Stability in continuous | Good | Good | Fair | Good | Fair | Excellent | Excellent | Fair | Fair | Excellent | Poor | Poor | Poor |
| discharge | | | | | | | | | | | | | |
| Polymer patternability | Good | Good | Good | Good | Good | Good | Good | Good | Good | Good | — | Good | Good |
| (100 μm) | | | | | | | | | | | | | |
| Polymer patternability | Good | Fair | Good | Good | Good | Good | Good | Good | Good | Good | — | Fair | Fair |
| (70 μm) | | | | | | | | | | | | | |
| Polymer patternability | Good | Fair | Good | Good | Fair | Good | Good | Good | Good | Good | — | Poor | Poor |
| (40 μm) | | | | | | | | | | | | | |
| Polymer patternability | Fair | Fair | Good | Good | Good | Good | Fair | Good | Good | Good | — | Poor | Fair |
| (10 mm square) | | | | | | | | | | | | | |

The results of Table 2 confirmed that the inkjet ink of the invention exhibited excellent stability in continuous discharge and excellent polymer patternability.

On the other hand, Comparative Inks 1 to 3 each of which did not have a predetermined weight-average boiling point could not satisfy these two properties. In particular, Comparative Ink 3 which had the same composition as that of the ink used in Examples of JP 2009-503806 A was inferior in both of the continuous discharge stability and polymer patternability.

[Manufacture of Surface Metal Film Material]

### [Preparation of Substrate]

A 7 wt % solution of ABS resin (Aldrich) in cyclohexane was applied to a glass epoxy substrate by spin coating at 250 rpm for 5 seconds and then at 750 rpm for 20 seconds and the solution was dried to form an adhesion promoting layer on the substrate. The adhesion promoting layer had a thickness of 2.4 μm and a surface roughness R_{z} of 0.4 μm.

[Preparation of Polymer Layer]

The inks prepared as above were used to form the polymer layer according to the method described below.

Each ink was discharged from the nozzles of an inkjet printer DMP-2831 (FUJIFILM Dimatix, Inc.) to draw a solid pattern with a size of 50 mm square (50 mm×50 mm) and the drying step and the exposure step were performed. The drying and exposure conditions were the same as those described above. The resulting polymer layer was directly bonded to the substrate and in particular to the adhesion promoting layer and the layer thickness is shown in Table 3. The inkjet head temperature during the ink discharge (temperature at which the ink was discharged) was 25° C.

[Application of Plating Catalyst]

Palladium nitrate (0.5 wt % with respect to the total solution amount) was dissolved in a mixed solution containing water and acetone at a weight ratio of 80/20. Insoluble matter was filtered off with a paper filter and the polymer layer to be plated was immersed in the filtrate for 15 minutes.

Then, the polymer layer to be plated was immersed for 15 minutes in a mixed solution containing water and acetone at a weight ratio of 80/20 and washed.

[Electroless Plating]

A Thru-Cup PGT (C. Uemura & Co., Ltd.) and the electroless plating bath of the composition indicated below were used.

The electroless plating bath was adjusted to a temperature of 30° C. and also adjusted to a pH of 13.0 with sodium hydroxide and sulfuric acid. The thus adjusted electroless plating bath was used to perform electroless plating. The thickness of the film formed by electroless plating was adjusted by changing the time of immersion in the plating bath.

(Composition of Electroless Plating Bath)

Distilled water: 79.2 wt %

PGT-A solution: 9.0 wt %

PGT-B solution: 6.0 wt %

PGT-C solution: 3.5 wt %

Formaldehyde (Wako Pure Chemical Industries, Ltd.): 2.3 wt %

[Electroplating]

Subsequently, the electroless Cu-plated film was used as the power supply layer to perform electroplating at 3 A/dm² for 15 minutes in the copper electroplating bath of the composition indicated below. Every sample had an electroplated copper film with a thickness of 15 to 16 μm.

(Composition of Electroplating Bath)

| | |
|---|---|
| Copper sulfate | 38 g |
| (Wako Pure Chemical Industries, Ltd.) | |
| Sulfuric acid | 95 g |
| (Wako Pure Chemical Industries, Ltd.) | |
| Hydrochloric acid | 1 mL |
| (Wako Pure Chemical Industries, Ltd.) | |
| Copper Gleam PCM (Meltex Inc.) | 3 mL |
| Water | 500 g |

[Evaluation of Adhesion]

A tensile tester RTM-100 (A & D Co., Ltd.) was used to measure the 90° peel strength of the resulting plated films with a width of 5 mm at a tensile strength of 10 mm/min. The films were rated “excellent” when the measured value was at least 0.5 kN/mm, “good” when the measured value was at least 0.35 kN/mm but less than 0.5 kN/mm, “fair” when the measured value was at least 0.2 kN/mm but less than 0.35 kN/mm, and “poor” when the measured value was less than 0.2 kN/mm. The results are shown in Table 3.

[Evaluation of Electroless Plating Properties]

The samples were rated “good” when an electroless plated film was formed as a result of immersion of the member to be plated in the electroless plating solution in the manufacture of the surface metal film material and “poor” when no electroless plated film was formed or the polymer film came off in the electroless plating solution. The results are shown in Table 3.

[Manufacture of Patterned Metal Material and Insulation Reliability Test]

An etching resist was formed in the region to be left for the metal pattern (wiring pattern) on the surface of the resulting plated film, and part of the plated film having no resist formed thereon was removed with a FeCl₃/HCl etching solution. Thereafter, the etching resist was removed with 3% NaOH solution as an alkali remover to form comb-shaped wiring (patterned metal material) for measuring the insulation reliability of the interconnects with a line width of 100 μm and a line-to-line space of 100 μm.

The comb-shaped wiring (five samples per plated film) was allowed to stand in a HAST tester (AM1-150S-25; ESPEC Corp.) at 125° C., 85% RH (unsaturated), a voltage applied of 10 V and a pressure of 2 atm for 200 hours to evaluate the interconnect insulation properties. The wiring was rated “excellent” when there was no change in the appearance or problem on the insulation properties, “good” when a tiny crystalline substance was found on the surface but there was no problem on the insulation properties, “fair” when a crystalline substance was dispersed on the surface and insulation failure occurred in one sample, and “poor” when insulation failure occurred in two or more samples. The results are shown in Table 3.

In the evaluation of the insulation properties, the wiring should not be rated “poor” for practical use and is more preferably rated “good” or “excellent” in terms of the use in various applications.

TABLE 3

| | | | | | | | | | | | Compara- |
|---|---|---|---|---|---|---|---|---|---|---|---|
| Evaluation | Example | Example | Example | Example | Example | Example | Example | Example | Example | Example | tive |
| method | 1 | 2 | 3 | 4 | 5 | 6 | 7 | 8 | 9 | 10 | Example 1 |
| Ink used | Ink 1 | Ink 2 | Ink 3 | Ink 4 | Ink 5 | Ink 6 | Ink 7 | Ink 8 | Ink 9 | Ink 10 | Compara- |
| | | | | | | | | | | | tive |
| | | | | | | | | | | | ink 3 |
| Thickness of | 0.7 | 0.4 | 0.8 | 0.8 | 0.9 | 1.1 | 0.5 | 1.6 | 1.1 | 1.3 | 1.1 |
| polymer | | | | | | | | | | | |
| film (μm) | | | | | | | | | | | |
| Electroless | Good | Good | Good | Good | Good | Good | Good | Good | Good | Good | Good |
| plating | | | | | | | | | | | |
| properties | | | | | | | | | | | |
| Thickness of | 0.5 | 0.6 | 0.3 | 0.3 | 0.3 | 1 | 0.8 | 0.5 | 0.6 | 1.2 | 1.1 |
| electroless | | | | | | | | | | | |
| plated film | | | | | | | | | | | |
| (μm) | | | | | | | | | | | |
| Plating adhesion | Excellent | Excellent | Excellent | Good | Good | Excellent | Good | Excellent | Good | Fair | Fair |
| Insulation | Excellent | Excellent | Excellent | Good | Good | Good | Fair | Excellent | Good | Fair | Poor |
| reliability | | | | | | | | | | | |
| test | | | | | | | | | | | |

Table 3 revealed that excellent results were obtained in the tests of the electroless plating properties, plating adhesion and insulation reliability when the inkjet ink of the invention was used. In the example using the cyano group-containing polymer, more excellent results were obtained in the plating adhesion and insulation reliability.

Comparative Example 1 had poor insulation reliability.

What is claimed is:

1. An inkjet ink comprising:
a polymer which contains a functional group capable of forming an interaction with a plating catalyst or its precursor and a polymerizable functional group; and
at least one solvent in which the polymer is dissolved or dispersed,
wherein an average boiling point (T_{(b)}) of the at least one solvent represented by formula (A):
$${T}_{( b )} = {\sum }_{i = 1}^{n} ( {W}_{i} \times {T}_{bi} ) \qquad Formula ( A )$$
(wherein Wᵢ represents a weight fraction of an ith solvent contained in the inkjet ink with respect to a total solvent amount and T_{bi} represents a boiling point of the ith solvent contained in the inkjet ink, and i represents an integer of 1 to n) is at least 150° C.

2. The inkjet ink according to claim 1, wherein the at least one solvent is a solvent mixture containing a solvent A with a boiling point of less than 180° C. and a solvent B with a boiling point of 180° C. or more and the solvent A is contained more than the solvent B on a weight basis.

3. The inkjet ink according to claim 1, wherein the inkjet ink has a viscosity at 25° C. of 50 mPa·s or less.

4. The inkjet ink according to claim 1, wherein the inkjet ink has a surface tension at 25° C. of 20 to 40 mN/m.

5. The inkjet ink according to claim 1, wherein the functional group capable of forming the interaction with the plating catalyst or its precursor is a non-dissociative functional group.

6. The inkjet ink according to claim 1, wherein the polymer has units represented by formulas (1) and (2): 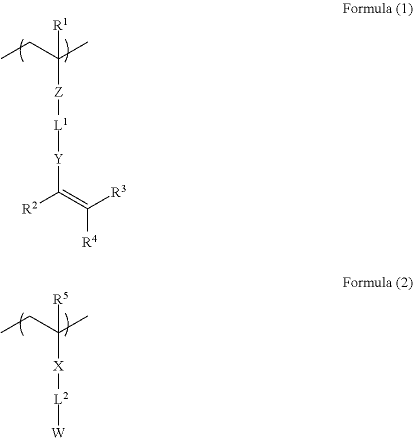
(in formula (1), R¹ to R⁴ are each independently a hydrogen atom or an optionally substituted alkyl group, Z and Y are each independently a single bond or an optionally substituted divalent organic group and L⁴ is an optionally substituted divalent organic group, and
in formula (2), R⁵ is a hydrogen atom or an optionally substituted alkyl group, X and L² are each independently a single bond or an optionally substituted divalent organic group, and W is a non-dissociative functional group capable of forming the interaction with the plating catalyst or its precursor).

7. The inkjet ink according to claim 1, wherein the polymer is contained in an amount of 1 to 20 wt % and the at least one solvent is contained in an amount of 80 to 99 wt %.

8. The inkjet ink according to claim 1, wherein the inkjet ink is used to form a polymer layer which is receptive to the plating catalyst or its precursor.

9. A method of manufacturing a surface metal film material having a metal film on a surface of a polymer layer, the method comprising:
a layer-forming step which includes applying the inkjet ink according to claim 1 onto a substrate by an inkjet system and curing the applied ink by heating or by exposure to light to form the polymer layer;
a catalyst applying step which includes applying a plating catalyst or its precursor to the polymer layer; and
a plating step which includes plating the polymer layer with the plating catalyst or its precursor.

10. The method according to claim 9, wherein the plating step is an electroless plating step and the metal film obtained by the electroless plating step has a thickness of 0.2 to 2.0 μm.

11. A surface metal film material obtained by the method according to claim 9.

12. A method of manufacturing a patterned metal material comprising:
a step of pattern-etching a metal film in the surface metal film material according to claim 11.

13. A circuit board comprising a patterned metal material obtained by the method according to claim 12.

14. A decorative material using the surface metal film material according to claim 11.

15. A method of manufacturing a patterned metal material having a patterned metal film on a surface of a polymer film, the method comprising:
a layer-forming step which includes applying the inkjet ink according to claim 1 onto a substrate in a pattern shape by an inkjet system and curing the applied ink by heating or by exposure to light to form the polymer layer in the pattern shape;
a catalyst applying step which includes applying a plating catalyst or its precursor to the polymer layer; and
a plating step which includes plating the polymer layer with the plating catalyst or its precursor.
